(19) United States
(12) Patent Application Publication
(10) Pub. No.: US 2026/0146362 A1
(43) Pub. Date: May 28, 2026

(54) Multizone Zone Reactor for Crystal Growth

(71) Applicant: Wolfspeed, Inc., Durham, NC (US)

(72) Inventors: Valeri Fedorovich Tsvetkov, Durham, NC (US); Brian Bennett Haidet, Raleigh, NC (US); Caleb Andrew Kent, Durham, NC (US); Yuri I. Khlebnikov, Raleigh, NC (US)

(21) Appl. No.: 19/239,693

(22) Filed: Jun. 16, 2025

Related U.S. Application Data
(63) Continuation-in-part of application No. 18/962,454, filed on Nov. 27, 2024.
(60) Provisional application No. 63/779,889, filed on Mar. 28, 2025.

(51) Int. Cl. C30B 23/06; C30B 29/36

(52) U.S. Cl. CPC C30B 23/06; C30B 29/36

(57) ABSTRACT

Crystal growth systems for growing crystalline material comprising silicon carbide are provided. In one example, the crystal growth system includes a crucible at least partially defining a crystal growth chamber. The crystal growth chamber has a plurality of zones, each zone associated with a different processing profile. The system includes a silicon carbide crystal. The system includes a source material.

### PRIORITY CLAIM

The present application claims the benefit of and priority to U.S. Provisional Patent Application Ser. No. 63/779,889, filed on Mar. 28, 2025, and is hereby incorporated by reference herein in its entirety. The present application is a continuation-in-part of and claims priority to U.S. patent application Ser. No. 18/962,454, filed on Nov. 27, 2024, and is hereby incorporated by reference herein in its entirety.

### FIELD

The present disclosure relates generally to crystal growth systems, such as silicon carbide crystal growth systems for growing crystalline silicon carbide semiconductor workpieces for fabrication of semiconductor devices.

### BACKGROUND

Semiconductor devices, including power semiconductor devices based on wide bandgap materials, may be formed on a semiconductor wafer as part of a semiconductor fabrication process. Single crystal silicon carbide (SiC) has proven to be a very useful wafer material in the manufacture of such semiconductor devices. Due to its physical strength and excellent resistance to many chemicals, silicon carbide may be used to fabricate very robust substrates adapted for use in the semiconductor industry. Silicon carbide has excellent electrical properties, including radiation hardness, high breakdown field, a relatively wide bandgap, high saturated electron drift velocity, high-temperature operation, and absorption and emission of high-energy photons in the blue, violet, and ultraviolet regions of the optical spectrum.

### SUMMARY

Aspects and advantages of embodiments of the present disclosure will be set forth in part in the following description, or can be learned from the description, or can be learned through practice of the embodiments.

In an aspect, the present disclosure provides an example crystal growth system for growing crystalline material. In some implementations, the example crystal growth system includes a crucible at least partially defining a crystal growth chamber, the crystal growth chamber comprising a plurality of zones, each zone associated with a different processing profile. In some implementations, the example crystal growth system includes a silicon carbide crystal. In some implementations, the example crystal growth system includes a source material. In some implementations, the example crystal growth system includes an interface structure configured to separate at least two zones of the plurality of zones in the crystal growth system.

In an aspect, the present disclosure provides an example crystal growth system for growing crystalline material. In some implementations, the example crystal growth system includes a crucible at least partially defining a crystal growth chamber, the crystal growth chamber comprising a first zone and a second zone. In some implementations, the example crystal growth system includes a source material in the first zone. In some implementations, the example crystal growth system includes a silicon carbide crystal in the second zone. In some implementations, the example crystal growth system includes an interface structure configured to separate the first zone and the second zone, the interface structure positioned at a location closer to the silicon carbide crystal relative to the source material.

In an aspect, the present disclosure provides an example crystal growth system for growing crystalline material. In some implementations, the example crystal growth system includes a crucible at least partially defining a crystal growth chamber. In some implementations, the example crystal growth system includes a silicon carbide crystal. In some implementations, the example crystal growth system includes a source material. In some implementations, the example crystal growth system includes a first heater about the crucible. In some implementations, the example crystal growth system includes a second heater about the crucible. In some implementations, at least a portion of the first heater overlaps at least a portion of the second heater.

In an aspect, the present disclosure provides an example crystal growth system. In some implementations, the example crystal growth system includes a crucible at least partially defining a crystal growth chamber, the crystal growth chamber comprising a first zone and a second zone. In some implementations, the example crystal growth system includes a source material in the first zone. In some implementations, the example crystal growth system includes a silicon carbide crystal in the second zone. In some implementations, a diameter associated with the first zone is larger than a diameter associated with the second zone.

In an aspect, the present disclosure provides an example crystal growth system. In some implementations, the example crystal growth system includes a crucible at least partially defining a crystal growth chamber. In some implementations, the example crystal growth system includes a silicon carbide crystal. In some implementations, the example crystal growth system includes a source material. In some implementations, the example crystal growth system includes a first heater about the crucible. In some implementations, the example crystal growth system includes a second heater about the crucible. In some implementations, the first heater and the second heater are configured to alter a temperature profile of at least a portion of the crucible through cumulative heat production.

In an aspect, the present disclosure provides an example crystal growth system. In some implementations, the example crystal growth system includes a crucible at least partially defining a crystal growth chamber, the crystal growth chamber including a plurality of zones, each zone associated with a different processing profile. In some implementations, the example crystal growth system includes a silicon carbide crystal. In some implementations, the example crystal growth system includes a source material. In some implementations, the example crystal growth system includes a first heater about the crucible. In some implementations, the example crystal growth system includes a second heater about the crucible. In some implementations, the first heater and the second heater are configured to alter a temperature profile of at least a portion of the crucible through cumulative heat production such that a localized hotspot is formed at the interface structure relative to a temperature profile of the silicon carbide crystal.

In an aspect, the present disclosure provides an example crystal growth system. In some implementations, the example crystal growth system includes a crucible at least partially defining a crystal growth chamber, the crystal growth chamber including a plurality of zones, each zone associated with a different processing profile. In some implementations, the example crystal growth system includes a silicon carbide crystal. In some implementations, the example crystal growth system includes a source material. In some implementations, the example crystal growth system includes an interface structure configured to separate at least two zones of the plurality of zones in the crystal growth system. In some implementations, the example crystal growth system includes a first heater about the crucible, wherein the first heater extends vertically about the crucible from a point at which the interface structure is disposed in the crystal growth system to a region at or beyond a seed holder. In some implementations, the example crystal growth system includes a second heater about the crucible, wherein the second heater extends vertically about the crucible from a point at which the interface structure is disposed in the crystal growth system to a region at or beyond the source material.

In an aspect, the present disclosure provides an example crystal growth system. In some implementations, the example crystal growth system includes a crucible at least partially defining a crystal growth chamber, the crystal growth chamber including a plurality of zones, each zone associated with a different processing profile. In some implementations, the example crystal growth system includes a silicon carbide crystal. In some implementations, the example crystal growth system includes a source material. In some implementations, the example crystal growth system includes an interface structure configured to separate at least two zones of the plurality of zones in the crystal growth system. In some implementations, the example crystal growth system includes at least one heater about the crucible, wherein the heater is disposed about the crucible such that the heater overlaps with a point at which the interface structure is disposed in the crystal growth system.

In an aspect, the present disclosure provides an example crystal growth system. In some implementations, the example crystal growth system includes a crucible at least partially defining a crystal growth chamber, the crystal growth chamber including a plurality of zones, each zone associated with a different processing profile. In some implementations, the example crystal growth system includes a silicon carbide crystal. In some implementations, the example crystal growth system includes a source material. In some implementations, the example crystal growth system includes an interface structure configured to separate at least two zones of the plurality of zones in the crystal growth system. In some implementations, the example crystal growth system includes a first heater about the crucible, wherein the first heater is disposed about the crucible such that the first heater provides a first heat distribution to the first zone. In some implementations, the example crystal growth system includes a second heater about the crucible, wherein the second heater is disposed about the crucible such that the second heater provides a second heat distribution to the second zone. In some implementations, the example crystal growth system includes a third heater about the crucible, wherein the third heater is disposed about the crucible such that the third heater overlaps with a point at which the interface structure is disposed in the crystal growth system, the third heater configured to provide a third heat distribution to a region closest in proximity to the interface structure.

In an aspect, the present disclosure provides an example crystal growth system. In some implementations, the example crystal growth system includes a crucible at least partially defining a crystal growth chamber, the crystal growth chamber including a plurality of zones, each zone associated with a different processing profile. In some implementations, the example crystal growth system includes a silicon carbide crystal. In some implementations, the example crystal growth system includes a source material. In some implementations, the example crystal growth system includes an interface structure configured to separate at least two zones of the plurality of zones in the crystal growth system. In some implementations, the example crystal growth system includes a first heater about the crucible. In some implementations, the example crystal growth system includes a second heater about the crucible. In some implementations, the first heater is a different type of heater relative to the second heater.

In an aspect, the present disclosure provides an example crystalline material. In some implementations, the example crystalline material includes a crucible at least partially defining a crystal growth chamber, the crystal growth chamber comprising a first zone and a second zone. In some implementations, the example crystalline material includes a silicon carbide crystal. In some implementations, the example crystalline material includes a source material. In some implementations, the example crystalline material includes one or more pumping circuits configured to provide a different processing profile in the first zone relative to the second zone.

Variations and modifications can be made to these example embodiments of the present disclosure.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussions of embodiments directed to one of ordinary skill in the art are set forth in the specification, which makes reference to the appended figures, in which:

FIG. 1 depicts an example crystal growth system according to aspects of the present disclosure.

FIG. 2 depicts an example crystal growth system according to aspects of the present disclosure.

FIG. 3 depicts an example crystal growth system according to aspects of the present disclosure.

FIG. 4 depicts an example crystal growth system according to aspects of the present disclosure.

FIG. 5 depicts an example crystal growth system according to aspects of the present disclosure.

FIG. 6 depicts an example crystal growth system according to aspects of the present disclosure.

FIG. 7 depicts an example crystal growth system according to aspects of the present disclosure.

FIG. 8 depicts an example coating on an interface structure according to aspects of the present disclosure.

FIG. 9 depicts an example crystal growth system according to aspects of the present disclosure.

FIG. 10 depicts an example crystal growth system according to aspects of the present disclosure.

FIG. 11 depicts an example crystal growth system according to aspects of the present disclosure.

FIG. 12 depicts an example crystal growth system according to aspects of the present disclosure.

FIG. 13 depicts an example crystal growth system according to aspects of the present disclosure.

FIG. 14 depicts an example crystal growth system according to aspects of the present disclosure.

FIG. 15 depicts an example crystal growth system according to aspects of the present disclosure.

FIG. 16 depicts an example crystal growth system according to aspects of the present disclosure.

FIG. 17 depicts an example crystal growth system according to aspects of the present disclosure.

FIG. 18 depicts an example crystal growth system according to aspects of the present disclosure.

FIG. 19 depicts an example crystal growth system according to aspects of the present disclosure.

FIG. 20 depicts an example crystal growth system according to aspects of the present disclosure.

FIG. 21 depicts an example crystal growth system according to aspects of the present disclosure.

FIG. 22 depicts an example crystal growth system according to aspects of the present disclosure.

FIG. 23 depicts an example crystal growth system according to aspects of the present disclosure.

FIG. 24 depicts an example crystal growth system according to aspects of the present disclosure.

FIG. 25 depicts an example crystal growth system according to aspects of the present disclosure.

FIG. 26 depicts an example crystal growth system according to aspects of the present disclosure.

FIG. 27 depicts an example crystal growth system according to aspects of the present disclosure.

FIG. 28 depicts an example crystal growth system according to aspects of the present disclosure.

FIG. 29 depicts an example crystal growth system according to aspects of the present disclosure.

FIG. 30 depicts an example crystal growth system according to aspects of the present disclosure.

FIG. 31 depicts an example crystal growth system according to aspects of the present disclosure.

FIG. 32 depicts an example crystal growth system according to aspects of the present disclosure.

FIG. 33 depicts an example crystal growth system according to aspects of the present disclosure.

FIG. 34 depicts an example crystal growth system according to aspects of the present disclosure.

FIG. 35 depicts an example crystal growth system according to aspects of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Example aspects of the present disclosure are directed to crystal growth systems (e.g., silicon carbide crystal growth systems) with a crystal growth chamber defined by one or more zones. Silicon carbide crystalline material may be produced using various seeded and unseeded sublimation crystal growth processes. In some example silicon carbide crystal growth processes, a seed crystal and a source material are arranged in a reaction crucible which is then heated to a sublimation temperature of the source material. By controlling heating of the reaction crucible, a thermal gradient is developed between the sublimating source material and the cooler seed crystal. As a result of the thermal gradient, source material in a vapor phase is transported onto the seed crystal where it is deposited to grow a solid bulk crystalline boule. This type of sublimation crystal growth process is commonly referred to as a physical vapor transport (PVT) process.

In some crystal growth systems and deposition systems, a sublimating source material is open to the seed crystal. A source zone and a vapor transport zone may be in direct proximity, coupled, or otherwise occur in the same general volume of a crystal growth chamber such that there is a lack of control over the thermal gradient, pressure, and/or chemical environment established by the crystal growth chamber. This may impact crystal growth parameters (e.g., growth rate, concentration of species, etc.) and crystallization (e.g., defect formation, stress in the crystal lattice, etc.). Crystal growth process parameters (e.g., PVT crystal growth process parameters) are driven through thermodynamic and kinetic factors. As such, sublimation of the source material and mass transport efficiency are tied to the thermal gradient, pressure, and vapor flux (e.g., chemical environment) established in a crystal growth system, where alterations or variations within the processing profile of the crystal growth chamber directly impacts crystal growth rate, crystal growth fronts, thermal and stress gradients in a growing crystal, etc. That is, variation (e.g., fluctuations in a process) or alteration (e.g., alteration of a thermal gradient, pressure, vapor flux, etc.) to the processing profile in a single zone reaction chamber may lead to undesired or subpar crystal growth. The processing profile established in a crystal growth system may impact the efficiency and quality assurance of a crystal growth process conducted in a crystal growth chamber as defect formation, including dislocations, stacking faults, or the incorporation of polycrystalline regions in a desired single-crystal lattice structure may occur.

Additionally, yield may be impacted as the height of a crystal grown in a crystal growth chamber is limited through a reduced effective growth rate, non-uniform growth, induced stress fields and crack formation, and/or disruptions to growth orientation caused by the processing profile of the crystal growth chamber. Further, a crystal grown in a crystal growth chamber may require additional processing steps to mitigate or reduce the effects described above, such as thermal annealing, which increases processing cost, processing time, and leads to more complex process control flow.

Still further, the lifespan and efficiency of reactor components, such as the seed holder, heating elements, insulators, electrodes, etc. are impacted through alterations to thermal loading (e.g., fluctuations and/or asymmetry of a thermal gradient) or, for example, increasing thermal loading to drive vapor diffusion and material transport. This may lead to increased cost for a crystal growth system as more consideration is needed for materials, reactor design, and process parameters of reactor components of a crystal growth system, as well as reduced machine uptime as repairs or replacement components are made. As such, the ability to tailor the processing profile (e.g., a temperature profile, pressure, transport of vapor, and/or chemical environment) to a particular crystal growth process, such as a PVT crystal growth process, would be useful.

According to example aspects of the present disclosure, one or more zones of a reaction crucible may be configured to provide different processing profiles. The different processing profiles may, for example, enhance sublimation and/or vapor transport in crystal growth systems and deposition systems (e.g., epitaxial reactors), such as silicon carbide crystal growth sublimation systems. The different processing profiles may provide more control over thermal gradients or otherwise accommodate the transport of source material vapor by enhancing control over radiation, thermal gradients, pressure, and/or a chemical environment established by the processing profile. For instance, in some examples, a processing profile of a vapor transport zone may be configured to enhance transport of vapor (e.g., source material vapor) to deposit on a growing crystal in a crystal growth process while a processing profile of a source zone may provide enhanced sublimation of source material. In some examples, the one or more zones may be provided through a physical separation of chemical environments and/or thermal gradients between a sublimating source material and a seed crystal experiencing deposition at a growth front. In some examples, the one or more zones (e.g., a thermal gradient in a source zone and a vapor transport zone) may be modified through volumetric or component considerations of the crucible.

Accordingly, aspects of the present disclosure are directed to a crystal growth system for growing crystalline material, the crystalline material including silicon carbide. The crystal growth system may include a crucible at least partially defining a crystal growth chamber. The crystal growth chamber may include a plurality of zones. Each zone of the plurality of zones may be associated with a different processing profile. The crystal growth system may include a seed holder configured to hold a silicon carbide seed crystal. The crystal growth system may include a source material. The crystal growth system may include an interface structure configured to separate at least two zones of the plurality of zones in the crystal growth system.

Another example aspect of the present disclosure is directed to a crystal growth system for growing crystalline material, the crystalline material including silicon carbide. The crystal growth system may include a crucible at least partially defining a crystal growth chamber. The crystal growth system may include a seed holder configured to hold a silicon carbide seed crystal. The crystal growth system may include a source material. The crystal growth system may include a first heater about the crucible. The crystal growth system may include a second heater about the crucible. At least a portion of the first heater may overlap at least a portion of the second heater.

Another example aspect of the present disclosure is directed to a crystal growth system for growing crystalline material, the crystalline material including silicon carbide. The crystal growth system may include a crucible at least partially defining a crystal growth chamber. The crystal growth chamber may include a first zone and a second zone. The crystal growth chamber may include a source material in the first zone. The crystal growth chamber may include a seed holder configured to hold a silicon carbide seed crystal in the second zone. A diameter associated with the first zone may be larger than a diameter associated with the second zone.

Aspects of the present disclosure provide technical effects and benefits. For instance, processing zones that divide the sublimating source material and the seed crystal may provide more control over radiative heat transfer between the sublimating source material and the seed. In general, modifications to the temperature of the seed crystal modifies the surface free energy of the seed crystal. The surface free energy plays a large role in the formation of the crystal lattice, defect sites, growth rate, etc. By providing more control over the processing profile (e.g., through one or more processing profiles) between the source material and the seed crystal, an enhanced level of control over surface energy of the seed may be achieved, which could result in a reduction of stresses in the crystal grown from the seed, enhanced crystal growth rate, and crystal growth uniformity or shape.

In addition, by providing multiple processing zones to the crystal growth system, the crystal growth system may be less sensitive to variations in crystal growth parameters. For instance, dividing the crystal growth chamber into a plurality of processing zones that modify the advective and convective transport of source vapor to the seed may provide control over the direction that vapor arrives at the seed, which may enhance deposition processes at the growth front of the seed crystal. Additionally, altering the path that vapor travels (e.g., shortening or elongating) or other factors (e.g., vapor velocity) alters the driving forces of diffusion, providing more control over growth parameters.

In addition, if a processing zone can be configured such that a large surface area of material that is non-reactive or inert with respect to carbon and silicon species is provided, the inert material may provide a catalytic surface that facilitates gas-gas reactions. That is, gas stoichiometry in the processing zone may be brought towards equilibrium. This may facilitate enhanced growth rates and less material waste as vapor source material is deposited more efficiently. In some embodiments, one or more of the processing zones may include (e.g., include within the processing zone or include as at least one boundary of the processing zone) an interface structure that may have a chemically active surface or coating that may be used to reduce contaminants, impurities, and inclusions in vapor transported through the processing zone.

Further, if a large surface area of material that is non-reactive or inert with respect to carbon and silicon species is provided, the inert material may provide a surface on which undesired contaminants may be adsorbed. In some instances, undesired species may be introduced to the reaction crucible that could damage reactor components, contaminate the source material, or be introduced to the seed crystal and form defects. A processing zone may be configured to filter the undesired species through adsorption (e.g., adsorption on an interface structure). Further, filtration of larger particles, such as carbon-based particulates released from reactor components which may lead to defects in a crystal growth process, may be possible. As such, delineating a crystal growth chamber into one or more processing zones provides multiple avenues to reduce defect formation within a crystal grown from a seed in a PVT process.

Further, by providing multiple processing zones configured through a volumetric consideration of the crystal growth chamber, larger (e.g., longer) high quality crystals may be produced as a volume of a source zone may be increased. In addition, the one or more processing profile(s) of the one or more processing zone(s) may potentially provide a second source (e.g., a carbon source). For instance, if a reactive material is provided to the one or more processing zones (e.g., uncoated or exposed graphite), the processing profile of the processing zone may be configured to etch the reactive material such that the reactive material contributes positively to species interacting with the seed crystal during a growth process. The reactive material may capture parasitic silicon carbide, or silicon carbide that crystallizes in an undesirable location, and act as a dynamic source if the captured silicon carbide is sublimated, if desired. Further, the reactive material may act as an additional gas injection site for process gases, or as an interface structure to physically separate or partition the one or more processing profiles.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “central portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel. “Non-perpendicular” means not perpendicular.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n+, n−, p+, p−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

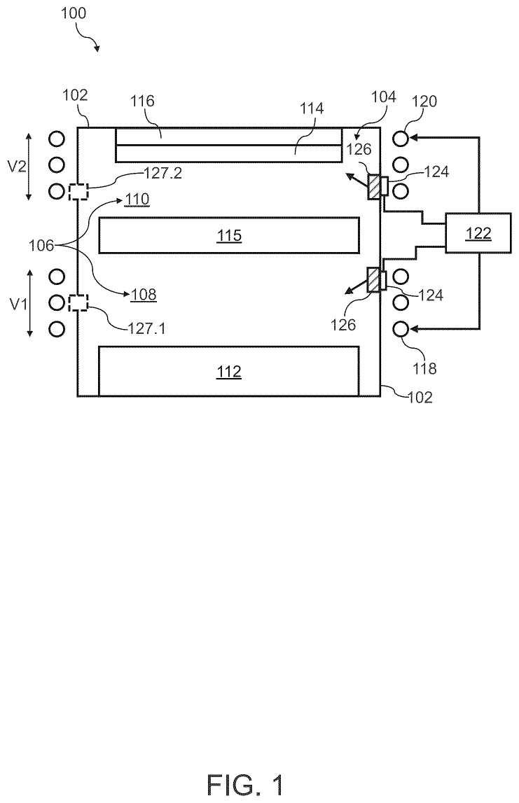

FIG. 1 is a cross-sectional schematic diagram of a crystal growth system 100 adapted for use in a crystal growth process of the type contemplated by certain embodiments of the disclosure. The crystal growth system 100 includes a reaction crucible 102 (also referred to as a susceptor or growth cell) that at least partially defines a crystal growth chamber 104. The reaction crucible 102 may be, at least in part, a graphite structure. The crystal growth chamber 104 may include a plurality of zones 106, such as a first zone 108 and a second zone 110, as depicted in FIG. 1. It will be understood that the crystal growth chamber 104 may include any number of zones, such as 3 zones, 4 zones, 5 zones, and the like.

An individual zone of the plurality of zones 106, such as the first zone 108 or the second zone 110, may be associated with a processing profile such that the differing zones are associated with different processing profiles. For instance, the first zone 108 can be associated with a first processing profile, and the second zone 110 can be associated with a second processing profile that is different from the first processing profile. The first processing profile of the first zone 108 may include a first temperature profile (e.g., temperature gradient), a first pressure, and a first vapor transport flux. The second processing profile of the second zone 110 may include a second temperature profile (e.g., temperature gradient), a second pressure, and a second vapor transport flux.

The first temperature profile of the first zone 108 may be the same as, or different from the second temperature profile of the second zone 110. For instance, the first temperature profile may be provided in a temperature range of about 1700° C. to about 2600° C. to the first processing profile of the first zone 108. The first temperature profile may refer to thermal energy provided in the form of an axial thermal gradient, radial thermal gradient, etc. such that a gradual temperature differential is formed in the first processing profile with respect to a source material 112 and a boundary of the first zone 108.

The second temperature profile may be provided in a temperature range of about 1700° C. to about 2600° C. to the second processing profile of the second zone 110, such that the second temperature profile of the second zone 110 is different than the first temperature profile of the first zone 108. The second temperature profile may refer to thermal energy provided in the form of an axial thermal gradient, a radial thermal gradient, etc. such that a gradual temperature differential is formed in the second processing profile with respect to a seed crystal 114 and a boundary of the second zone 110.

In some examples, the first temperature profile may be optimized or tailored to provide a desired radial thermal gradient and the second temperature profile may be optimized or tailored to provide a desired axial thermal gradient, or vice versa.

In some examples, the first zone 108 may have a first pressure and the second zone 110 may have a second pressure that is different from the first pressure. In some embodiments, the second pressure is less than the first pressure. In some embodiments, the second pressure is greater than the first pressure. In some embodiments, each of the first zone 108 and the second zone 110 may be associated with an independent pumping circuit or other pressure regulation circuit to independently regulate the pressure in the first zone 108 relative to the second zone 110. For instance, the first zone 108 may be associated with a first optional pumping circuit 127.1 and the second zone 110 may be associated with a second optional pumping circuit 127.2. In some examples, different gases and/or gas compositions may be provided into the first zone 108 relative to the second zone. For instance, the independent pumping circuits 127.1, 127.2 for each of the first zone 108 and the second zone 110 may provide carbon-containing gases, silicon-containing gases, dopant containing gases (e.g., n-type dopants, such as nitrogen-containing gas, phosphorus-containing gases; and/or p-type dopants, such as boron-containing gases, aluminum containing gases), and/or other reactive or non-reactive gases. In some examples, the independent pumping circuits 127.1, 127.2 for each of the first zone 108 and the second zone 110 may provide different flux, local pressure, and/or composition in the first zone 108 relative to the second zone 110. Inlet(s), outlet(s), and/or pump(s) for the pumping circuits 127.1, 127.2 can be located in any suitable arrangement in the growth chamber, such as on the top, side, bottom, etc.

A seed holder 116 may be configured to position the seed crystal 114 in the crystal growth chamber 100. As depicted in FIG. 1, the seed crystal 114 may be positioned in the second zone 110 of the crystal growth chamber 100. A silicon carbide vapor source material 112 may be provided in the first zone 108 of the crystal growth chamber 100. During a crystal growth process, silicon carbide vapor or other vapor may be transported from the source material 112 to the seed crystal 114 to grow a crystalline material boule on the seed crystal 114. The source material 112 may be a powdered silicon carbide source material, solid silicon carbide source material, carbon and/or silicon source material, etc. Example silicon carbide source materials are disclosed in U.S. application Ser. No. 18/963,103, filed on Nov. 27, 2024 and in U.S. application Ser. No. 18/963,117, filed on Nov. 27, 2024, both of which are incorporated herein by reference.

For instance, in some examples, the silicon carbide source material includes a shaped solid silicon carbide source material structure. In some embodiments, the structure may have a composite shape. As used herein, “composite shape” and “composite shaped” refer to any three-dimensional object or component that deviates from a regular cylindrical shape, or a composite solid structure containing multiple shaped solids which may have simple or complex shapes. Deviations from a cylindrical shape include forms with regular or irregular geometries that do not conform to the typical circular or elliptical cross-section of a cylinder. Such structures may exhibit various shapes, including but not limited to structures with polygonal cross-sections; irregularly curved structures; and shapes with holes, voids, surface variations, or combinations thereof. The term also includes shapes containing multiple interconnected or distinct substructures. The substructures may themselves be composite shaped or may be cylindrically shaped. The term encompasses a wide range of geometric configurations and excludes objects that maintain a uniform cylindrical profile throughout their entire volume.

As used herein, “shaped solid” and “solid structure” refer to non-powdered solid components. A non-powdered component, for example, can have a size in at least one dimension of about 1 μm or greater, such as about 10 μm or greater, such as about 50 μm or greater, such as about 100 μm or greater, such as about 200 μm or greater, such as about 1000 μm or greater, such as about 1700 μm or greater, such as about 5 mm or greater, such as about 10 mm or greater. In some example embodiments, a shaped solid or solid structure may be formed by binding powdered particles together to form a composite material. Shaped solids may be shaped in an intentional manner to influence relevant properties, such as sublimation rate, vapor flow paths, thermal gradients, etc. Shaped solids may have one or more shape modifications. Shape modifications are intentional modifications to a source structure to influence relevant properties, such as sublimation rate, vapor flow paths, thermal gradients, etc.

In some embodiments, a composite shaped structure may include complex geometry including shapes, features, symmetry, asymmetry, dimensions, thicknesses, and/or appendages to improve such parameters. In some embodiments, the shaped solid source material may have features that provide desired thermal gradients within the source material. In some embodiments, the shaped solid source material may have features that provide high surface area for better sublimation rates. In some embodiments, the shaped solid source material may have features that provide desired gas flow paths through the source material to efficiently transport the sublimated SiC. In some embodiments, the shaped solid source material may have features that are tailored based on known local variations (e.g., temperature variations) within the crucible. In some embodiments, the shaped solid source material may have features that allow for directional control of the gas flow or heat flow within the source. In some embodiments, the shaped solid source material may have features that allow for control of the sublimation rate over time. Such features are described in more detail below with reference to the drawings.

The source material can be intentionally shaped to control the sublimation rate over time and thus during various stages of crystal growth. The source material can also be shaped to obtain a desired vapor flow/local vapor pressure relative to the seed/growing crystal surface.

In some embodiments, the silicon carbide source material structure may contain multiple layers varying in at least one property. For example, it may include an outer layer and an inner layer such that when used in a sublimation process, the outer layer sublimates first, followed by the inner layer. Varying the properties of the layers can affect the sublimation properties (e.g., rate, temperature required) and crystal growth properties (e.g., polytype, dopant concentration, defect concentration, shape, growth rate).

In some embodiments, the silicon carbide source material structure includes a dopant. The inclusion of a dopant in the source material provides a method for incorporating the dopant into the silicon carbide crystal. This is particularly useful for incorporating dopants which are not easily incorporated using a vapor source.

As depicted in FIG. 1, the system may include an interface structure 115 between the first zone 108 and the second zone 110. In some examples, such as the example depicted in FIG. 1, the interface structure 115 may physically separate the first zone 108 and the second zone 110. In some examples, the interface structure 115 is positioned at a location in the reaction crucible 102 that is closer to the seed holder 116 relative to the source material 112. In some examples, the interface structure 115 may be positioned in a range of about 0.5 cm to about 10 cm from the seed holder 116, such as about 1 cm to about 6 cm, such as about 3 cm to about 5 cm. In some examples, the interface structure 115 may include a baffle structure. The baffle structure may be graphite (e.g., porous graphite, coated graphite, etc.). The baffle structure may have one or more apertures or may be made from a porous material to allow for the passage of vapor. Example baffle structures that may be used are disclosed in U.S. patent application Ser. No. 18/962,454, filed on November 27, 2024 which is incorporated herein by reference. Any of the interface structures provided herein may extend across a portion or all of the width or flux path of a growth chamber.

For instance, in some examples, the baffle structure includes a porous material, such as porous graphite. In some examples, at least a portion of the baffle structure has a porosity of greater than about 50% by volume, such as greater than about 70% by volume, such as greater than 80% by volume. Porosity by volume expressed as a percentage refers to the percentage of the volume of voids in the baffle relative to the total volume of the material. In some embodiments, the baffle has a porosity in a range of about 50% to about 97%, such as about 80% to about 97%, such as about 85% to about 97%.

In some embodiments, the baffle structure includes one or more apertures defined through a thickness of the baffle. As used herein, an “aperture” is a defined opening, space, perforation, hole, or void in a structure that extends from one exterior surface of a structure to another exterior surface of the structure. In some embodiments, the baffle has a long dimension that is generally non-perpendicular to the growth surface of the seed crystal. In some examples, the one or more apertures include a plurality of holes defined through the baffle. In some examples, the one or more apertures include an annular aperture defined through a thickness of the baffle. In some examples, a vapor transport direction through the one or more apertures is in a non-perpendicular direction relative to the growth surface of the seed crystal.

In some examples, the one or more apertures are arranged in the baffle to provide for non-uniform vapor transport from the source material to the seed crystal. In some examples, the one or more apertures are arranged in the baffle to provide for asymmetric vapor transport from the source material to the seed crystal. In some examples, the one or more apertures include a first aperture and a second aperture, wherein a width of the first aperture is different from a width of the second aperture. In some examples, the one or more apertures include a first plurality of apertures and a second plurality of apertures, wherein a density of the first plurality of apertures in the baffle is different from a density of the second plurality of apertures in the baffle.

In some examples, the baffle includes a plurality of dividers arranged in a non-perpendicular direction relative to the growth surface of the seed crystal. In some examples, the one or more apertures are arranged to direct vapor in a direction that is more towards a center of the seed crystal relative to a peripheral portion of the seed crystal. In some examples, the one or more apertures are arranged to direct vapor in a direction that is more towards a peripheral portion of the seed crystal relative to a central portion of the seed crystal.

In some examples, the baffle includes a plurality of baffle structures (e.g., baffle plates). In some examples, the baffle includes a first baffle plate having the one or more apertures and a second baffle plate with no apertures. In some examples, the baffle includes a first baffle plate comprising a first aperture and a second baffle plate comprising a second aperture. In some examples, the first aperture is aligned with the second aperture. In some examples, the first aperture is not aligned with the second aperture.

In some examples, one or more portions of the baffle element, coating, surface or subsurface treatment for the baffle or any of its parts may include an engineered structure having a construction or configuration that is or includes one or more of a porous structure, woven wire, perforated plate, foam, screen printed material, refractory metal, 3D printed structure, coated wire, carbon fiber mesh, carbon wires, refractory metal wires, woven mesh, cast component(s), grid, sintered powder, composite laminate, electroformed structure, braided wire, honeycomb structure, felt structure, nanostructured film, carbon nanotubes, tightly or loosely interconnected network of structures or other suitable construction or configuration. Portions or the entirety of any of the foregoing may be coated, treated and/or converted to form a metal carbide surface, subsurface or entire article of metal carbide. One or more combinations of any of these constructions or configurations may be used without deviating from the scope of the present disclosure. For example, in some embodiments, a first baffle structure (e.g., a first baffle plate) may include a first configuration (e.g., porous material) and a second baffle structure (e.g., a second baffle plate) may include a second configuration (e.g., honeycomb structure). In some examples, the baffle structure may be a secondary source or may comprise a secondary source, such as a secondary carbon source (e.g., if the interface structure comprises graphite).

In some examples, the interface structure 115 may be positioned such that a first vapor transport flux (e.g., F1, a first matter transport rate) in the first zone 108 is different than a second vapor transport flux (e.g., F2, a second matter transport rate) in the second zone 110. In some examples, the first vapor transport flux (e.g., F1) is less than the second vapor transport flux (e.g., F2) such that an energetic incentive is provided to source vapor to deposit on the growth front of the seed crystal 114 rather than another portion of the crystal growth chamber 104, such as the interface structure 115. Modifications of the processing profile (e.g., temperature profile, chemical environment, pressure, kinetics factors such as transport path, etc.) through the position of the interface structure 115 may enhance deposition of source vapor from the source material 112 on the seed crystal 114 to grow the crystalline material boule.

Further, by physically separating the first zone 108 and the second zone 110, the interface structure 115 may reduce a thermal interaction between at least two zones of the plurality of zones 106. Thermal interactions in a crystal growth process may lead to variations or fluctuations in a thermal processing profile, which may alter a thermal gradient established between the source material 112 and the seed crystal 114. Additionally, variations in a thermal processing profile may impact growth uniformity, defect formation, and mass transport (e.g., vapor flux). It is desirable to have stable, consistent thermal processing profiles in a crystal growth system. As discussed in relation to FIGS. 12, 15, 19, 23 and 26, the first zone 108 and the second zone 110 may not be separated by a physical structure, but rather, the first zone 108 and the second zone 110 may be delineated by another component of the crystal growth system 100, e.g., such as a sidewall of the crucible or structure on the sidewall of the crucible.

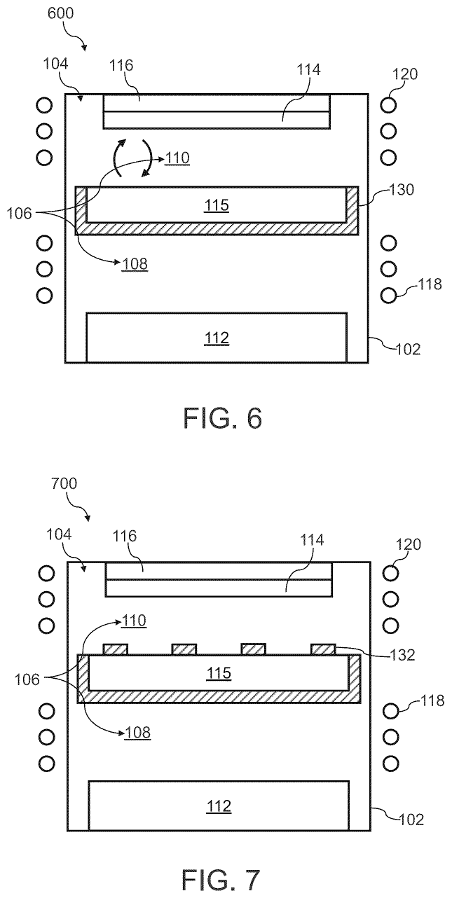

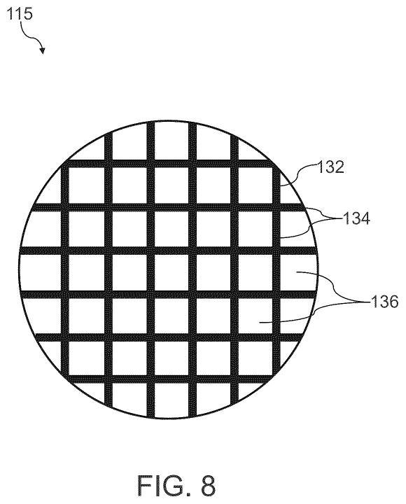

In some examples, the interface structure 115 may include a graphite material. In some examples, the interface structure 115 may include a porous graphite material. The porous graphite material may have a porosity in a range of about 40% to about 97%, such as in a range of about 70% to about 97%. In some examples, the interface structure 115 may include one or more apertures. In some examples, the interface structure 115 may include a coating, for instance, as discussed in relation to FIGS. 6 and 7. In some examples, the coating may be a patterned coating on a surface of the interface structure 115 facing the seed holder 116, for instance, as discussed in reference to FIGS. 7 and 8.

Referring again to FIG. 1, the first pressure of the first processing profile of the first zone 108 may be the same as, or different from the second pressure of the second processing profile of the second zone 110. For instance, modification of sublimation of the source material 112 may be achieved by modification of the first pressure of the first processing profile of the first zone 108. Modification of defect formation may be achieved by modifying the second pressure of the second processing profile of the second zone. Similarly, as discussed above, the first vapor transport flux of the first processing profile of the first zone 108 may be the same as, or different from the second vapor transport flux of the second processing profile of the second zone 110. For instance, the species, concentration, or rate of transport in the first zone 108 may be the same as, or differ from the species, concentration, or rate of transport in the second zone 110.

The crystal growth system 100 may include a first heater 118 adapted to heat the first zone 108 of the reaction crucible 102. The first heater 118 may be an induction heater (e.g., a radio frequency (RF) heater). Alternatively, the first heater 118 of the reaction crucible 102 may be a resistive heater. Using any competent heating mechanism and approach, the temperature within the first processing profile of the first zone 108 of the crystal growth system 100 may be controllable. Similarly, the crystal growth system 100 may include a second heater 120 adapted to heat the second zone 110 of the reaction crucible 102. The second heater 120 may be an induction heater (e.g., an RF heater). Alternatively, the second heater 120 may be a resistive heater. Using any competent heating mechanism and approach, the temperature within the second processing profile of the second zone 110 of the crystal growth system 100 may be controllable.

In some examples, such as the example depicted in FIG. 1, the first heater 118 may extend vertically about the reaction crucible 102 from a point at which the interface structure 115 is disposed in the crystal growth system 100 to a region at or beyond the seed crystal 114 or the seed holder 116. The second heater 120 may extend vertically about the reaction crucible 102 from a point at which the interface structure 115 is disposed in the crystal growth system 100 to a region at or beyond the source material 112. In some examples, the first heater 118 and the second heater 120 may not extend past the interface structure 115 or other reactor component that delineates the crystal growth chamber 104 into the plurality of processing zones 106.

In some examples, at least one of the first heater 118 or the second heater 120 may have a non-uniform density of heat distribution elements. For instance, the first heater 118 may have a non-uniform density of coils disposed about the first heater 118. The first heater 118 may include variations in material properties in the heat distribution elements that impact the transfer of thermal energy along a portion of the first heater 118. The first heater 118 may include intentional design features to impede or enhance the transfer of thermal energy along a portion of the first heater 118. Similarly, the second heater 120 may have a non-uniform density of coils disposed about the second heater 120. The second heater 120 may include variations in material properties in the heat distribution elements that impact the transfer of thermal energy along a portion of the second heater 120. The second heater 120 may include intentional design features to impede or enhance the transfer of thermal energy along a portion of the second heater 120. The non-uniform density of heat distribution elements may have a highest density of heat distribution elements or transfer of thermal energy at a point nearest the interface structure 115.

In some examples, such as the example depicted in FIG. 1, at least one of the first heater 118 or the second heater 120 may be movable during a crystal growth process with respect to the reaction crucible 102 or other components of the crystal growth system 100. For instance, the first heater 118 may be configured to move in a vertical direction as indicated by arrow V1. The second heater 120 may be configured to move in a vertical direction as indicated by arrow V2. In some examples, the first heater 118 may be moved independently of the second heater 120. For instance, the first heater may be moved based on process parameters associated with the first zone 108. The second heater 120 may be moved based on process parameters associated with the second zone 110. In some examples, the first heater 118 and the second heater 120 may be moved together as one unit at the same time. In some examples, the crucible 102 may be moved relative to the first heater 118 and/or the second heater 120.

The crystal growth system 100 may include one or more control devices 122. In some embodiments, the one or more control devices 122 may include one or more microcontrollers, microprocessors operable to execute instructions stored in one or more memory devices to implement operations and control components of the crystal growth system 100, or other suitable device for implementing any of the methods described herein.

In some embodiments, the one or more control devices 122 may be operable to independently control the first heater 118 or second heater 120. The crystal growth system 100 may include at least one sensor 124. As depicted in FIG. 1, the sensor 124 may be positioned such that data is obtained for a processing profile parameter (e.g., temperature, pressure, flux, etc.) in at least one of the first zone 108 or the second zone 110. The crystal growth system 100 may include a sensor window 126 positioned on the crucible. In some examples, the sensor window 126 may include quartz. In some examples, the sensor window 126 may include sapphire. The sensor 124 may be one or more of a pyrometer, thermocouple, non-contact sensor or other suitable sensor. The one or more control devices 122 may be operable to independently control at least one of the first heater 118 or the second heater 120 based on data obtained from the sensor 124. In addition, and/or in the alternative, the first heater 118 or the second heater 120 may be jointly controlled (e.g., at a fixed proportion of power delivery). In some examples, the first heater 118 and/or the second heater 120 may be controlled such that the first heater 118 or the second heater 120 provide continuous thermal output (e.g., a thermal gradient may be established and remain unchanged in a respective zone during a crystal growth process).

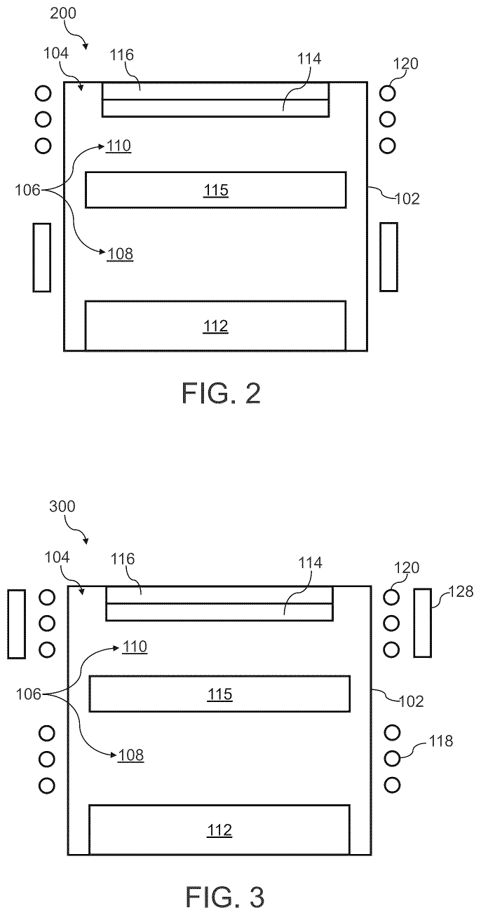

In some examples, the one or more sensors 124 may include a first sensor 124 associated with the first zone 108 and a second sensor 124 associated with the second zone 110 as illustrated in FIG. 1. In some embodiments, the sensor(s) 124 may be associated with a first zone, second zone, other zone, or interface structure between zones. In some embodiments, the sensor(s) 124 can be optional. In some embodiments, the sensor(s) 124 can be associated with single or multiple zones and positioned in single or multiple locations across multiple zones or between zones or at an interface structure. It will be understood that the one or more control devices 122, the one or more sensors 124, and/or the sensor window 126 may be included in any of the examples provided herein, such as any of the crystal growth systems of FIGS. 2 through 7, and 9 through 35.

In some examples, the crystal growth system 100 may include one or more actuators. The actuators may be configured to impart translational and/or rotational movement to one or more components of the crystal growth system 100, such as the seed holder 116 and crystalline material 114, the source material 112, the insulation, the heating elements 118 and 120, the interface structure 115, the crucible 102, and/or other elements. The actuator(s) may be include any suitable type of actuator, such as an electric actuator (e.g., servo motor, stepper motor, linear motor, DC motor, AC motor, rotary motor), piezoelectric actuator, pneumatic actuator (e.g., pneumatic cylinder, pneumatic diaphragm), hydraulic actuator (e.g., hydraulic cylinder), electromagnetic actuator (e.g., solenoid), thermal actuator (e.g., shape memory alloy actuator, bimetallic actuator), vacuum actuator (e.g., vacuum suction actuator) and/or other suitable actuator, rotary actuator (e.g., screwing arrangement). The actuator(s) may be operate independently of each other to cause relative positioning of components relative to other components. For instance, in some embodiments, the source 112 may be rotated independently of the crystalline material 114. In some embodiments, one or more actuators may be operable to move the crystalline material 114 (e.g., the growth face of the crystalline material) to different vertical positions relative to the source material 112 during a crystal growth process. For instance, one or more actuators may move the crystalline material 114 and/or the source material 112 such that there is a first transport distance between the crystalline material 114 and the source material 112 for a first process period. One or more actuators may move the crystalline material 114 and/or the source material 112 such that there is a second transport distance (e.g., different from the first transport distance) between the crystalline material 114 and the source material 112 for a second process period. Those of ordinary skill in the art, using the disclosure provided herein, will understand that any type of actuator may be used to move components without deviating from the scope of the present disclosure. The actuator(s) may be used in any of the crystal growth systems provided herein.

FIG. 2 is a cross-sectional schematic diagram of a crystal growth system 200 adapted for use in a crystal growth process of the type contemplated by certain embodiments of the disclosure. Like the crystal growth system 100 of FIG. 1, the crystal growth system 200 of FIG. 2 includes the reaction crucible 102, the crystal growth chamber 104, a plurality of zones 106 including the first zone 108 and the second zone 110, the source material 112, the seed crystal 114, the seed holder 116, the first heater 118, and the second heater 120.

The crystal growth system 200 may include the first heater 118 adapted to heat the first zone 108 of the reaction crucible 102. The first heater 118 may be an induction heater (e.g., an RF heater). Alternatively, the first heater 118 of the reaction crucible 102 may be a resistive heater. Using any competent heating mechanism and approach, the temperature within the first processing profile of the first zone 108 of the crystal growth system 100 may be controllable. Similarly, the crystal growth system 200 may include a second heater 120 adapted to heat the second zone 110 of the reaction crucible 102. The second heater 120 may be an induction heater (e.g., an RF heater). Alternatively, the second heater 120 may be a resistive heater. Using any competent heating mechanism and approach, the temperature within the second processing profile of the second zone 110 of the crystal growth system 200 may be controllable.

As depicted in FIG. 2, the first heater 118 and the second heater 120 may be configured to be different types of heaters, such that the heating mechanism of the first zone 108 differs with respect to the heating mechanism of the second zone 110. For instance, the first heater 118 may be a resistive heater and the second heater 120 may be an inductive heater.

FIG. 3 is a cross-sectional schematic diagram of a crystal growth system 300 adapted for use in a crystal growth process of the type contemplated by certain embodiments of the disclosure. Like the crystal growth systems of FIGS. 1 and 2, the crystal growth system 300 of FIG. 3 includes the reaction crucible 102, the crystal growth chamber 104, a plurality of zones 106 including the first zone 108 and the second zone 110, the source material 112, the seed crystal 114, interface structure 115, the seed holder 116, the first heater 118, and the second heater 120.

The crystal growth system 300 may include a third heater 128 adapted to heat the second zone 110 of the reaction crucible 102. The third heater 128 may be an induction heater (e.g., an RF heater). Alternatively, the third heater 128 of the reaction crucible 102 may be a resistive heater. Using any competent heating mechanism and approach, the temperature profile within the second processing profile of the first zone 108 of the crystal growth system 100 may be controllable. Similarly, the crystal growth system 100 may include the second heater 120 adapted to heat the second zone 110 of the reaction crucible 102. The second heater 120 may be an induction heater (e.g., an RF heater). Alternatively, the second heater 120 may be a resistive heater. Using any competent heating mechanism and approach, the temperature within the second processing profile of the second zone 110 of the crystal growth system 100 may be controllable.

As depicted in FIG. 3, the second heater 120 and the third heater 128 may be configured to be different types of heaters. The third heater 128 may at least partially overlap the second heater 120. The second heater 120 and the third heater 128 may work together to control the temperature profile in the second zone 110.

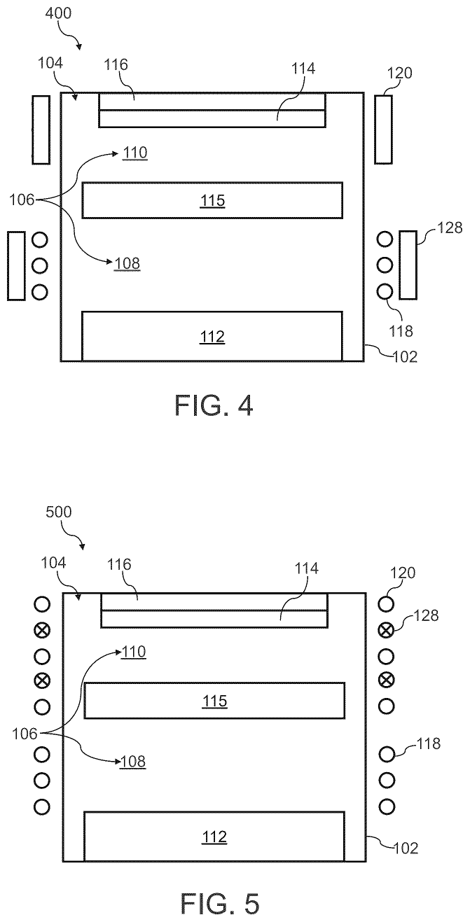

FIG. 4 is a cross-sectional schematic diagram of a crystal growth system 400 adapted for use in a crystal growth process of the type contemplated by certain embodiments of the disclosure. Like the crystal growth systems of FIGS. 1 through 3, the crystal growth system 400 of FIG. 4 includes the reaction crucible 102, the crystal growth chamber 104, a plurality of zones 106 including the first zone 108 and the second zone 110, the source material 112, the seed crystal 114, interface structure 115, the seed holder 116, the first heater 118, and the second heater 120.

The crystal growth system 400 may include the third heater 128 adapted to heat the first zone 108 of the reaction crucible 102. The third heater 128 may be an induction heater (e.g., an RF heater). Alternatively, the third heater 128 of the reaction crucible 102 may be a resistive heater. Using any competent heating mechanism and approach, the temperature profile within the first processing profile of the first zone 108 of the crystal growth system 100 may be controllable. Similarly, the crystal growth system 100 may include the second heater 120 adapted to heat the second zone 110 of the reaction crucible 102. The second heater 120 may be an induction heater (e.g., an RF heater). Alternatively, the second heater 120 may be a resistive heater. Using any competent heating mechanism and approach, the temperature within the second processing profile of the second zone 110 of the crystal growth system 100 may be controllable.

As depicted in FIG. 4, the first heater 118 and the third heater 128 may be configured to be different types of heaters. The third heater 128 may at least partially overlap the first heater 118. The first heater 118 and the third heater 128 may work together to control the temperature profile in the first zone 108.

FIG. 5 is a cross-sectional schematic diagram of a crystal growth system 500 adapted for use in a crystal growth process of the type contemplated by certain embodiments of the disclosure. Like the crystal growth systems of FIGS. 1 through 4, the crystal growth system 500 of FIG. 5 includes the reaction crucible 102, the crystal growth chamber 104, a plurality of zones 106 including the first zone 108 and the second zone 110, the source material 112, the seed crystal 114, interface structure 115, the seed holder 116, the first heater 118, the second heater 120, and the third heater 128.

As depicted in FIG. 5, the second heater 120 and the third heater 128 may be arranged to heat the second zone 110. The coils of the third heater 128 and the coils of the second heater 120 may be interleaved. The second heater 120 and the third heater 128 may be controlled independently of each other to control the temperature profile of the second zone 110. The second heater 120 and the third heater 128 may cumulatively contribute to the temperature profile of the second zone 110 with differing inputs.

In some examples, the second heater 120 and the third heater 128 may be different types of heaters that are alternated or interleaved to provide the thermal processing profile in the same processing zone (e.g., the second zone 110 as depicted in FIG. 5.) It will be appreciated that many combinations of heating element designs, configurations, or combinations may be created to alter the temperature profile of any given zone of the reaction crucible 102.

FIG. 6 is a cross-sectional schematic diagram of a crystal growth system 600 adapted for use in a crystal growth process of the type contemplated by certain embodiments of the disclosure. Like the crystal growth systems of FIGS. 1 through 5, the crystal growth system 600 of FIG. 6 includes the reaction crucible 102, the crystal growth chamber 104, a plurality of zones 106 including the first zone 108 and the second zone 110, the source material 112, the seed crystal 114, the interface structure 115, the seed holder 116, the first heater 118, and the second heater 120.

As depicted in FIG. 6, the interface structure 115 may at least partially include a coating 130. The coating 130 may leave a portion of the interface structure 115 exposed. As depicted in FIG. 6, the portion of the interface structure 115 that is exposed may be in closer proximity to the seed crystal 114 than the source material 112. In some examples, the coating 130 may be positioned on at least one major surface of the interface structure 115, such as a top portion facing the seed crystal 114 or a bottom surface facing the source material 112. As depicted in FIG. 6, the coating 130 may be configured such that a majority of the surfaces of the interface structure 115 are coated, for instance, such that one or more regions in closest proximity to a sidewall portion of the interface structure 115 and a bottom surface of the interface structure 115 closest to the source material 112 are coated with the coating 130. The coating 130 may be positioned on an exposed surface of the interface structure 115 such that at least a portion of the interface structure 115 is open to the processing environment of the reaction crucible 102.

In some examples, the coating 130 is a pyrolytic coating. In some examples, the coating 130 includes tantalum carbide. Other suitable coatings may be used without deviating from the scope of the present disclosure, such as other carbide coatings, such as vanadium carbide, silicon carbide, etc. Example coatings that may be used are disclosed in U.S. application Ser. No. 18/963,196, filed on Nov. 27, 2024, U.S. application Ser. No. 18/963,136, filed on Nov. 27, 2024, and U.S. application Ser. No. 18/963,240, filed on Nov. 27, 2024, which are incorporated herein by reference.

In some embodiments, a coating may include metal particles and a binder that forms a matrix holding the particles together in a coating. In some embodiments, the metal may be tantalum. In some embodiments, the metal particles may be less than 10 microns in diameter. In some embodiments, the binder may be a thermally curable resin. In some embodiments, the metal particles may be functionalized with compounds that promote particle dispersion in the coating and may couple to the binder. In some embodiments, the coating is stable in air, forms a stable suspension, and can be used to dip-coat or paint parts. In some embodiments, solvent may be added to the coating, for example to tune the viscosity of the coating, tune the metal particle concentration, or tune the coating uniformity. In some embodiments, a compound that promotes sintering may be added to the coating mixture to promote sintering of the particles (e.g., at temperatures above 1000° C.). The thickness of the final coating may be able to be controlled, for example by varying the concentration of metal particles in the coating and by varying the deposition volume of the coating onto the surface or part.

In some embodiments, a coating be created by applying an organometallic compound to at least one surface of a structure, wherein the at least one surface of the structure contains carbon or an oxide, curing the organometallic compound on the at least one surface of the structure; and heating the organometallic compound on the at least one surface of the structure such that the metal carbide coating is formed on the at least one surface of the structure, wherein the organometallic compound includes a central metal atom; and ligands capable of forming polydentate bonds to the central metal atom.

In some embodiments, the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof. In some embodiments, the central metal atom is tantalum. In some embodiments, the ligands capable of forming polydentate bonds to the central metal atom are polar. In some embodiments, the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

In some examples, furanic ultra high temperatures adhesives (UHTAs) may be used as a binder in a paint that converts to a coating, such as solution processable ceramic coatings (e.g., TaC, NbC, SiC, etc.) or a non-ceramic coating (e.g., glassy carbon coatings). Certain furan functionalized compound can be used as ultra-high temperature adhesives. The chemistry of furan rings allows a broad range of furan-containing polymeric, molecular, or inorganic-organic hybrid materials that can function as UHTAs. Examples of such materials incorporating the furan heterocycle as a structural unit include: furanic polymers and resins; furanic molecules and macromolecules; furanic rigid network solids; and furan functionalized micromaterials or nanomaterials.

With the proper material design, the furanic constituents would allow these compounds to participate in crosslinking (curing) through Diels-Alder cycloaddition and the formation of a bonded glassy carbon (BGC) network. Crosslinking, which forms a three-dimensional polymeric network, can be initiated through the application of chemical, photochemical, thermal, mechanical, or electrical energy. Once cured, these materials become structurally robust solids that bind strongly to a substrate. As these cured solids are pyrolized, the furan constituents undergo ring opening and forming reactive alkene fragments (CH2═CH2) and radicals which drive the formation of and condensation of polyaromatic cores resulting in a BGC network, which results in an UHTA.

The adhesion of furanic UHTAs may be further improved through the incorporation of a filler material. Use of such filler materials with UHTAs as a binding agent may be referred to as a “brick and mortar” model. Such filler materials may improve the adhesive properties of the UHTA by mechanical reinforcement. During pyrolysis of the furanic UHTA, the filler or any products generated by the chemical change of the filler may be incorporated into the network as a structural unit and mechanically strengthen the resulting BGC network through covalent bonding and/or strong non-covalent interactions. Such filler materials may also improve the adhesive properties of the UHTA by promoting carbon condensation. During pyrolysis of the furanic UHTA, the filler or any products generated by the chemical change of the filler may aid in the condensation of intermediate polyaromatic cores through covalent bonding and/or strong non-covalent interactions. By contributing to the condensation, a denser BGC network may be produced.

In some embodiments, filler materials used with furanic UHTAs may be active or may be passive. Active fillers undergo a chemical change (e.g., thermal decomposition, reduction, oxidation, solid state synthesis, etc.) into one or more products during the pyrolysis of the UHTA. Active fillers may also change aggregate state or are subject to diffusion before or during undergoing a chemical change. Passive fillers can form covalent bonds or participate in strong non-covalent interactions with the BGC network, but do not undergo further chemical reactions during the pyrolysis of the UHTA. Passive fillers can be impermeable or can be porous, allowing the furanic UHTA to penetrate into the material. In the case of a porous filler, the BGC network may form inside and outside the filler material during the pyrolysis of the UHTA. Passive fillers may participate in sintering, recrystallization, surface or bulk diffusion processes during temperature exposure. Either active or passive fillers may also create voids or porosity during temperature treatments. For example, fillers may decompose or evaporate to create voids in the UHTA.

The coating 130 may provide thermal protection, corrosion resistance, particle filtration, or other property to the interface structure 115 in a crystal growth process. As depicted in FIG. 6, a portion of the interface structure 115 may be exposed (e.g., not coated). In this way, the interface structure 115 may act as a secondary source for the crystal growth process. Silicon species that are not initially formed into the crystalline material may interact with the exposed portion of the interface structure 115 to generate disilicon carbide or silicon dicarbide (e.g., Si₂C or SiC₂) intermediate species in the presence of a carbon-based material (e.g., the interface structure 115) which may enhance or provide beneficial avenues for growth kinetics, mass transport, morphology of a growing crystal, control over a growth front, and defect formation. The density of the exposed portion may be nonuniformly distributed across the interface structure 115.

FIG. 7 is a cross-sectional schematic diagram of a crystal growth system 700 adapted for use in a crystal growth process of the type contemplated by certain embodiments of the disclosure. Like the crystal growth systems of FIGS. 1 through 6, the crystal growth system 700 of FIG. 7 includes the reaction crucible 102, the crystal growth chamber 104, a plurality of zones 106 including the first zone 108 and the second zone 110, the source material 112, the seed crystal 114, the interface structure 115, the seed holder 116, the first heater 118, and the second heater 120, and the coating 130.

As depicted in FIG. 7, the interface structure 115 may at least partially include a patterned coating 132. The coating 132 may be patterned on at least one major surface of the interface structure 115, such as a top portion facing the seed crystal 114 or a bottom surface facing the source material 112 of the interface structure 115. As depicted in FIG. 7, the coating 130 may be configured such that a majority of the surfaces of the interface structure 115 are coated, for instance, such that one or more regions in closest proximity to a sidewall portion of the interface structure 115 and a bottom surface of the interface structure 115 closest to the source material 112 are fully coated. The patterned coating 132 may be provided on an exposed surface of the interface structure 115 such that at least a portion of the interface structure 115 is open to the processing environment of the reaction crucible 102.

FIG. 8 depicts a top-down view of the interface structure 115 with a patterned coating 132. The patterned coating 132 may be provided to a surface of the interface structure 115 through a plurality of interconnected structures 134. The interconnected structures 134 may be provided in a predetermined pattern such that the patterned coating 132 includes a grid structure. However, other suitable patterns may be used without deviating from the scope of the present disclosure. The exposed portions 136 (e.g., uncoated portions) of the interface structure 115 are depicted as being square portions, however, the exposed portions 136 may include any shape or configuration such as triangular in shape, circular in shape, diamond shaped, hexagonal in shape, and so forth.

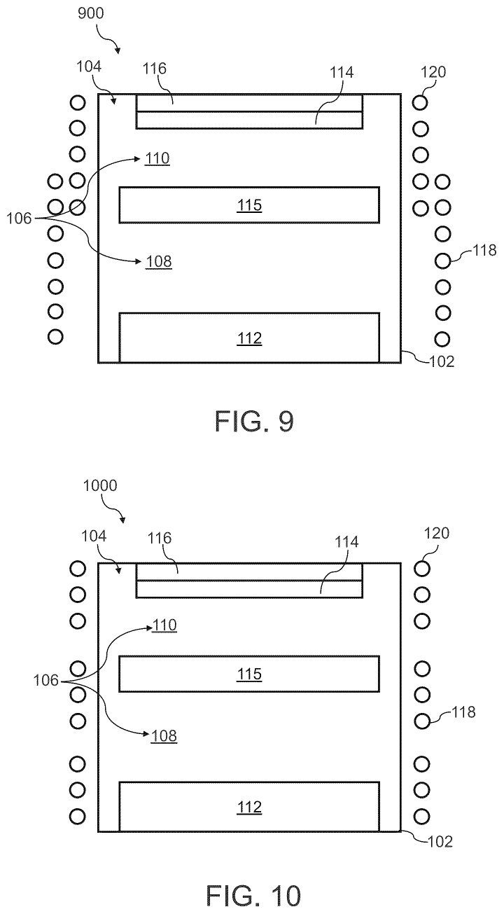

FIG. 9 is a cross-sectional schematic diagram of a crystal growth system 900 adapted for use in a crystal growth process of the type contemplated by certain embodiments of the disclosure. Like the crystal growth systems of FIGS. 1 through 7, the crystal growth system 900 of FIG. 9 includes the reaction crucible 102, the crystal growth chamber 104, a plurality of zones 106 including the first zone 108 and the second zone 110, the source material 112, the seed crystal 114, interface structure 115, the seed holder 116, the first heater 118, and the second heater 120.

As depicted in FIG. 9, at least a portion of the first heater 118 may overlap at least a portion of the second heater 120. The first heater 118 and the second heater 120 may at least partially overlap at a point at which the interface structure 115 is disposed in the crystal growth system 900. The first heater 118 and the second heater 120 may not extend past the interface structure 115 into another processing profile or processing zone of the reaction crucible 102. The portion of the first heater 118 that overlaps with the portion of the second heater 120 may be configured to provide cumulative heat production such that a localized hotspot is formed at the interface structure 115. Increasing the temperature profile of the interface structure 115 may reduce deposition on the interface structure 115 during a crystal growth process.

FIG. 10 is a cross-sectional schematic diagram of a crystal growth system 1000 adapted for use in a crystal growth process of the type contemplated by certain embodiments of the disclosure. Like the crystal growth systems of FIGS. 1 through 7 and 9, the crystal growth system 1000 of FIG. 10 includes the reaction crucible 102, the crystal growth chamber 104, a plurality of zones 106 including the first zone 108 and the second zone 110, the source material 112, the seed crystal 114, interface structure 115, the seed holder 116, the first heater 118, the second heater 120, and the third heater 128.

The crystal growth system 1000 may include the first heater 118 adapted to heat the first zone 108 of the reaction crucible 102. The first heater 118 may be an induction heater (e.g., an RF heater). Alternatively, the first heater 118 of the reaction crucible 102 may be a resistive heater. Using any competent heating mechanism and approach, the temperature within the first processing profile of the first zone 108 of the crystal growth system 1000 may be controllable.

Similarly, the crystal growth system 200 may include a second heater 120 adapted to heat the second zone 110 of the reaction crucible 102. The second heater 120 may be an induction heater (e.g., an RF heater). Alternatively, the second heater 120 may be a resistive heater. Using any competent heating mechanism and approach, the temperature within the second processing profile of the second zone 110 of the crystal growth system 200 may be controllable.

The crystal growth system 1000 may include the third heater 128 positioned between the first heater 118 and the second heater 120. In some examples, such as the example depicted in FIG. 10, the first heater 118 and the second heater 120 do not overlap with the third heater 128. In some examples, at least one of the first heater 118 or the second heater 120 may at least partially overlap with the third heater 128. The third heater 128 may be disposed at a vertical location on the reaction crucible 102 at least partially about the interface structure 115. That is, the third heater 128 may be positioned about the reaction crucible 102 such that third heater 128 overlaps with a point at which the interface structure 115 is disposed in the crystal growth system 1000. The third heater 128 may be configured to provide high temperature to the interface structure 115, for instance, to reduce deposition on the interface structure and/or to promote sublimation of the interface structure 115. The third heater 128 may be independently controllable relative to the first heater 118 and the second heater 128.

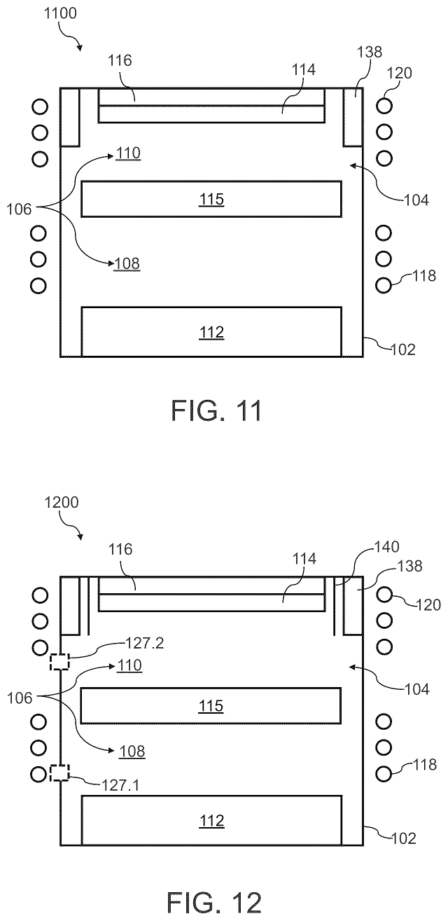

FIG. 11 is a cross-sectional schematic diagram of a crystal growth system 1100 adapted for use in a crystal growth process of the type contemplated by certain embodiments of the disclosure. Like the crystal growth systems of FIGS. 1 through 7 and 9 through 10, the crystal growth system 1100 of FIG. 11 includes the reaction crucible 102, the crystal growth chamber 104, a plurality of zones 106 including the first zone 108 and the second zone 110, the source material 112, the seed crystal 114, interface structure 115, the seed holder 116, the first heater 118, and the second heater 120.

The crystal growth system 1100 may further include an insulator structure 138 within the crucible at least partially surrounding the seed holder 116. The insulator structure 138 may include graphite. In some examples, the insulator structure 138 may be tapered such that the insulator structure 138 includes a non-uniform diameter along at least a portion of the insulator structure 138. As discussed in relation to FIGS. 6 and 7, the insulator structure 138 may alter a temperature profile or chemical environment of an associated processing profile in the second zone proximate the seed holder.

FIG. 12 is a cross-sectional schematic diagram of a crystal growth system 1200 adapted for use in a crystal growth process of the type contemplated by certain embodiments of the disclosure. Like the crystal growth systems of FIGS. 1 through 7 and 9 through 11, the crystal growth system 1200 of FIG. 12 includes the reaction crucible 102, the crystal growth chamber 104, a plurality of zones 106 including the first zone 108 and the second zone 110, the source material 112, the seed crystal 114, the seed holder 116, interface structure 115, the first heater 118, and the second heater 120. The crystal growth system 1200 may include the insulator structure 138.

The crystal growth system 1100 may include a ring crystallizer structure 140. The ring crystallizer structure 140 may at least partially surround the seed holder 116. In some examples, the ring crystallizer structure 140 may include a carbide material. For instance, the ring crystallizer structure 140 may include tantalum carbide, vanadium carbide, etc. As discussed in relation to FIG. 6, the ring crystallizer structure 140 may enhance or provide beneficial avenues for growth kinetics, mass transport, morphology of a growing crystal, control over a growth front, and defect formation.

As illustrated in FIG. 12, the first zone 108 may be associated with a first optional pumping circuit 127.1 an the second zone 110 may be associated with a second optional pumping circuit 127.2. In some examples, different gases and/or gas compositions may be provided into the first zone 108 relative to the second zone 110. For instance, the independent pumping circuits 127.1, 127.2 for each of the first zone 108 and the second zone 110 may provide carbon-containing gases, silicon-containing gases, dopant containing gases (e.g., n-type dopants, such as nitrogen-containing gas, phosphorus-containing gases; and/or p-type dopants, such as boron-containing gases, aluminum containing gases), and/or other reactive or non-reactive gases. In some examples, the independent pumping circuits 127.1, 127.2 for each of the first zone 108 and the second zone 110 may provide different flux, local pressure, and/or composition in the first zone 108 relative to the second zone 110. Inlet(s), outlet(s), and/or pump(s) for the pumping circuits 127.1, 127.2 can be located in any suitable arrangement in the growth chamber, such as on the top, side, bottom, etc.

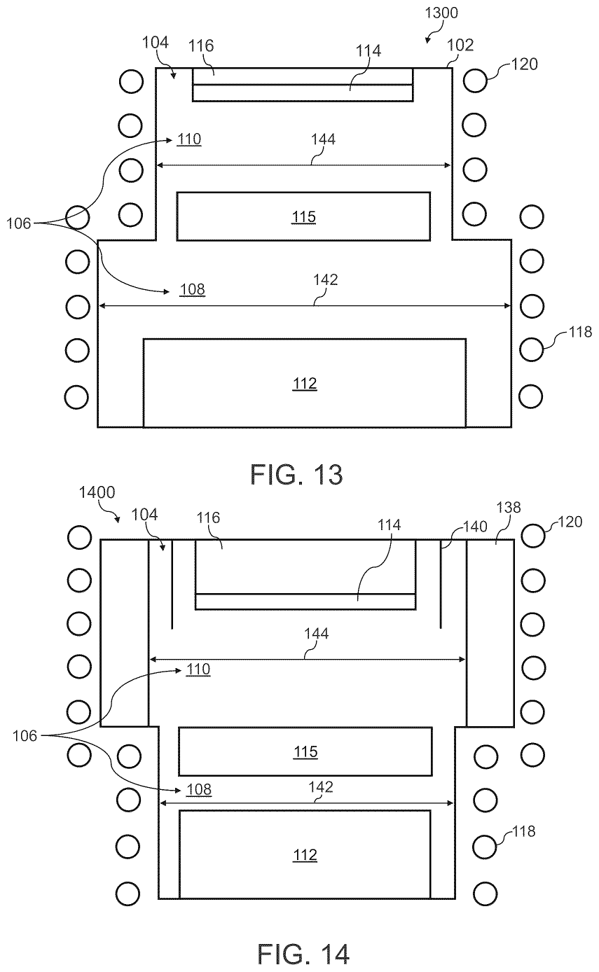

FIG. 13 is a cross-sectional schematic diagram of a crystal growth system 1300 adapted for use in a crystal growth process of the type contemplated by certain embodiments of the disclosure. Like the crystal growth systems of FIGS. 1 through 7 and 9 through 12, the crystal growth system 1300 of FIG. 13 includes the reaction crucible 102, the crystal growth chamber 104, a plurality of zones 106 including the first zone 108 and the second zone 110, the source material 112, the seed crystal 114, interface structure 115, the seed holder 116, the first heater 118, and the second heater 120.

As depicted in FIG. 13, the first zone 108 of the plurality of zones 106 of the crystal growth system 1300 may be associated with a first diameter 142 and the second zone 110 of the plurality of zones 106 of the crystal growth system 1300 may be associated with a second diameter 144. The first diameter 142 may be larger than the second diameter 144. The first diameter 142 being larger than the second diameter 144 may allow a larger volume of the source material 112 to occupy the first zone 108. Additionally, the volume difference in the first zone 108 with respect to the second zone 110 may alter the processing profile(s) of the first zone 108 and the second zone 110 such that a physical separation (e.g., the interface structure 115) is optional.

FIG. 14 is a cross-sectional schematic diagram of a crystal growth system 1400 adapted for use in a crystal growth process of the type contemplated by certain embodiments of the disclosure. Like the crystal growth systems of FIGS. 1 through 7 and 9 through 13, the crystal growth system 1400 of FIG. 14 includes the reaction crucible 102, the crystal growth chamber 104, the plurality of zones 106 including the first zone 108 and the second zone 110, the source material 112, the seed crystal 114, interface structure 115, the seed holder 116, the first heater 118, and the second heater 120. The crystal growth system 1400 may include the ring crystallizer structure 140 and the insulator structure 138.

As depicted in FIG. 14, the first zone 108 of the plurality of zones 106 of the crystal growth system 1300 may be associated with a first diameter 142 and the second zone 110 of the plurality of zones 106 of the crystal growth system 1300 may be associated with a second diameter 144. The first diameter 142 may be smaller than the second diameter 144. The first diameter 142 that is smaller than the second diameter 144 may allow more volume in the second zone 110 to accommodate other reactor components, such as the ring crystallizer structure 140 or the insulator structure 138. Additionally, the volume difference in the first zone 108 with respect to the second zone 110 may alter the processing profile(s) of the first zone 108 and the second zone 110 such that a physical separation (e.g., the interface structure 115) is optional.

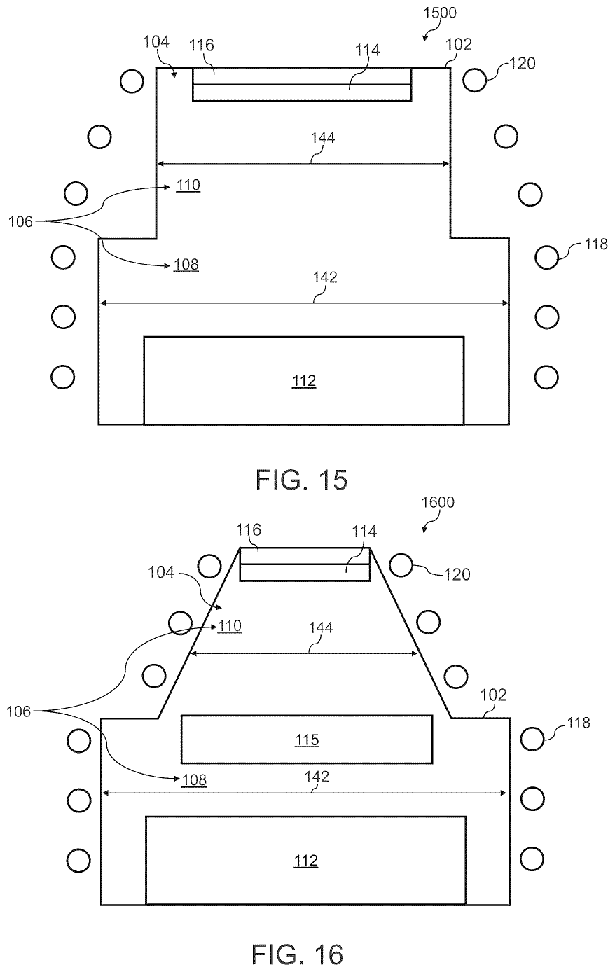

FIG. 15 is a cross-sectional schematic diagram of a crystal growth system 1500 adapted for use in a crystal growth process of the type contemplated by certain embodiments of the disclosure. Like the crystal growth systems of FIGS. 1 through 7 and 9 through 14, the crystal growth system 1500 of FIG. 15 includes the reaction crucible 102, the crystal growth chamber 104, the plurality of zones 106 including the first zone 108 and the second zone 110, the source material 112, the seed crystal 114, the seed holder 116, the first heater 118, and the second heater 120. The reaction crucible 102 may include the first diameter 142 and the second diameter 144 as discussed in relation to FIG. 13.

As depicted in FIG. 15, the second heater 120 may include a tapered coil such that a horizontal distance of the second heater 120 from the reaction crucible 102 is non-uniform along a vertical dimension of the reaction crucible 102. In some examples, such as the example depicted in FIG. 15, the tapered coil of the second heater 120 may include a horizontal distance from the reaction crucible 102 that is smaller with respect to a position on the second heater 120 nearest to the seed holder 116. Similarly, the tapered coil of the second heater 120 may include a horizontal distance from the reaction crucible 102 that is larger with respect to a position on the second heater 120 nearest to the first zone 108. Alternatively, in some examples, the tapered coil of the second heater 120 may include a horizontal distance from the reaction crucible 102 that is larger with respect to a position on the second heater 120 nearest to the seed holder 116. Similarly, the tapered coil of the second heater 120 may include a horizontal distance from the reaction crucible 102 that is smaller with respect to a position on the second heater 120 nearest to the first zone 108.

The tapered coil of the second heater 120 may alter a temperature profile of processing profile of the second zone 110 such that the processing profile of the first zone 108 and the processing profile of the second zone 110 are not physically separated. It will be appreciated that the first heater 118 or the second heater 120 may have a tapered coil, and may be combined with any of the crystal growth systems contemplated by the present disclosure.

FIG. 16 is a cross-sectional schematic diagram of a crystal growth system 1600 adapted for use in a crystal growth process of the type contemplated by certain embodiments of the disclosure. Like the crystal growth systems of FIGS. 1 through 7 and 9 through 15, the crystal growth system 1600 of FIG. 16 includes the reaction crucible 102, the crystal growth chamber 104, the plurality of zones 106 including the first zone 108 and the second zone 110, the source material 112, the seed crystal 114, interface structure 115, the seed holder 116, the first heater 118, and the second heater 120.

As depicted in FIG. 16, the first zone 108 of the plurality of zones 106 of the crystal growth system 1600 may be associated with the first diameter 142 and the second zone 110 of the plurality of zones 106 of the crystal growth system 1600 may be associated with a non-uniform diameter 144. The first diameter 142 may be larger than the non-uniform diameter 144. The first diameter 142 being larger than the non-uniform diameter 146 may allow a larger volume of the source material 112 to occupy the first zone 108 relative to a crystal growth system with a uniform diameter.

Additionally, the non-uniform diameter 146 of the second zone 110 may be configured such that the non-uniform diameter 146 (e.g., a non-uniform diameter 146.1) is largest nearest the first zone 108. The non-uniform diameter (e.g., a non-uniform diameter 146.2) may be smaller closer to the seed crystal 114. The non-uniform diameter 146 of the second zone 110 may alter the processing profile of the second zone 110 to modify crystal growth kinetics, mass transport, morphology of a growing crystal, control over a growth front, and defect formation.

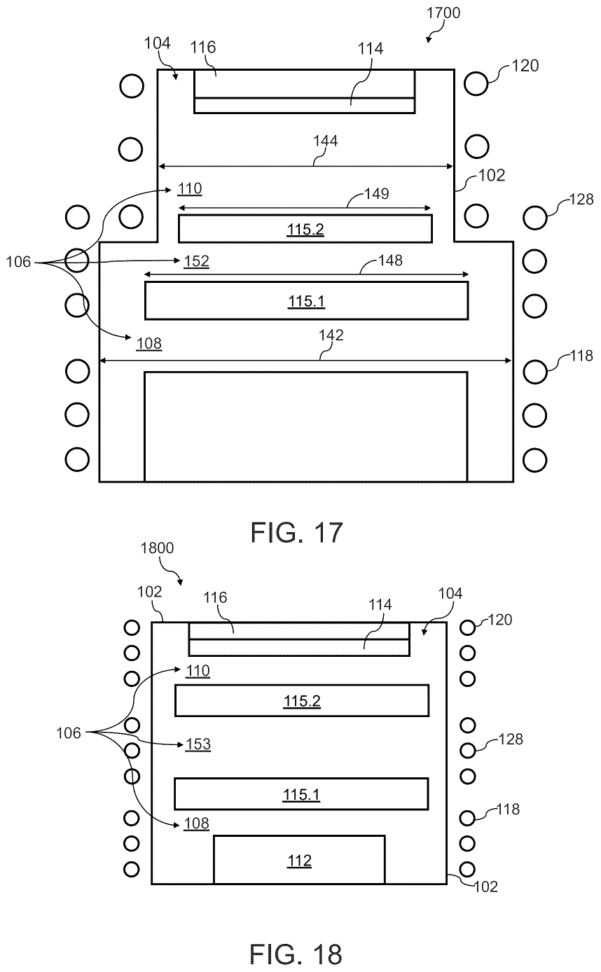

FIG. 17 is a cross-sectional schematic diagram of a crystal growth system 1700 adapted for use in a crystal growth process of the type contemplated by certain embodiments of the disclosure. Like the crystal growth systems of FIGS. 1 through 7 and 9 through 16, the crystal growth system 1700 of FIG. 17 includes the reaction crucible 102, the crystal growth chamber 104, the plurality of zones 106 including the first zone 108 and the second zone 110, the source material 112, the seed crystal 114, the interface structure 115, the seed holder 116, the first heater 118, and the second heater 120. The reaction crucible 102 may include the first diameter 142 and the second diameter 144 as discussed in relation to FIG. 13.

As depicted in FIG. 17, the interface structure 115 may include a first interface structure 115.1 and a second interface structure 115.2. The first interface structure 115.1 may include a first interface diameter 148 and a second interface structure 115.2 may include a second interface diameter 149. The first interface diameter 148 and the second interface diameter 149 may differ. For example, as depicted in FIG. 17, the first interface diameter 148 may be larger than the second interface diameter 149. In other examples, such as examples where the first diameter 142 is smaller than the second diameter 144, the first interface diameter 148 may be smaller than the second interface diameter 149. In other examples, the first interface diameter 148 and the second interface diameter 149 may differ irrespective of a diameter of the crystal growth chamber 104. The first interface structure 115.1 and a second interface structure 115.2 may define a third zone 153. The third zone 153 may include a third processing profile (e.g., a third temperature profile, a third pressure, a third vapor flux, and/or a third chemical environment) that may be tuned to enhance crystal growth as described herein.

As depicted in FIG. 17, the crystal growth system 1700 may include the third heater 128. At least a portion of the second heater 120 may overlap at least a portion of the third heater 128. The second heater 120 and the third heater 128 may at least partially overlap at a point at which the interface structure 115 (e.g., the second interface structure 115.2) is disposed in the crystal growth system 1700. The first heater 118 and the second heater 120 may not extend past the interface structure 115 (e.g., the first interface structure 115.1 or the second interface structure 115.2) into another processing profile or processing zone of the reaction crucible 102. The portion of the first heater 118 that overlaps with the portion of the third heater 128 may be configured to provide cumulative heat production such that a localized hotspot is formed at the second interface structure 115.2. Increasing the temperature profile of the second interface structure 115.2 may enhance the formation of intermediate species contributing to the processing profile of the second zone 110 and enhance mass transport factors to drive deposition on the growth front of the seed crystal 114.

In some examples, such as the example depicted in FIG. 17, the first heater 118 does not overlap with the third heater 128. It will be understood that a number of configurations may be created, such as a configuration where the first heater 118 and the third heater 128 at least partially overlap in addition to the second heater 120 and the third heater 128 at least partially overlapping. Further, in some examples, the first heater 118 and the third heater 128 may at least partially overlap, whereas the second heater 120 may be configured not to overlap with the third heater 128. Further, in some examples, neither the first heater 118 nor the second heater 120 may overlap with the third heater 128.

FIG. 18 is a cross-sectional schematic diagram of a crystal growth system 1800 adapted for use in a crystal growth process of the type contemplated by certain embodiments of the disclosure. Like the crystal growth systems of FIGS. 1 through 7 and 9 through 17, the crystal growth system 1800 of FIG. 18 includes the reaction crucible 102, the crystal growth chamber 104, the plurality of zones 106 including the first zone 108 and the second zone 110, the source material 112, the seed crystal 114, the interface structure 115, the seed holder 116, the first heater 118, and the second heater 120. The crystal growth system 1800 may include the third heater 128.

As depicted in FIG. 18, the interface structure 115 may include the first interface structure 115.1 and the second interface structure 115.2. The first interface structure 115.1 and a second interface structure 115.2 may define a third zone 153. The third zone 153 may include a third processing profile (e.g., a third temperature profile, a third pressure, a third vapor flux, and/or a third chemical environment) that may be tuned to enhance crystal growth as described herein.

As depicted in FIG. 18, the crystal growth system 1800 may include the third heater 128. The third heater 128 may not overlap with the first heater 118 or the second heater 120. In some examples, at least a portion of the second heater 120 may overlap at least a portion of the third heater 128. The second heater 120 and the third heater 128 may at least partially overlap at a point at which the interface structure 115 (e.g., the second interface structure 115.2) is disposed in the crystal growth system 1800. Similarly, in some examples, at least a portion of the first heater 118 may overlap at least a portion of the third heater 128. The first heater 118 and the third heater 128 may at least partially overlap at a point at which the interface structure 115 (e.g., the second interface structure 115.1) is disposed in the crystal growth system 1800.

The first heater 118 and the second heater 120 may not extend past the interface structure 115 (e.g., the first interface structure 115.1 or the second interface structure 115.2) into another processing profile or processing zone of the reaction crucible 102. Increasing the temperature profile of the interface structure 115 (e.g., the first interface structure 115.1 or the second interface structure 115.2) may enhance the formation of intermediate species contributing to the processing profile of the second zone 110 and enhance mass transport factors to drive deposition on the growth front of the seed crystal 114.

In some examples, such as the example depicted in FIG. 18, neither the first heater 118 nor the second heater 120 do not overlap with the third heater 128. It will be understood that a number of configurations may be created, such as a configuration where the first heater 118 and the third heater 128 at least partially overlap. For example, a configuration where the second heater 120 and the third heater 128 are at least partially overlapping may be formed. Further, in some examples, the first heater 118 and the third heater 128 at least partially overlap, whereas the second heater 120 may be configured not to overlap with the third heater 128.

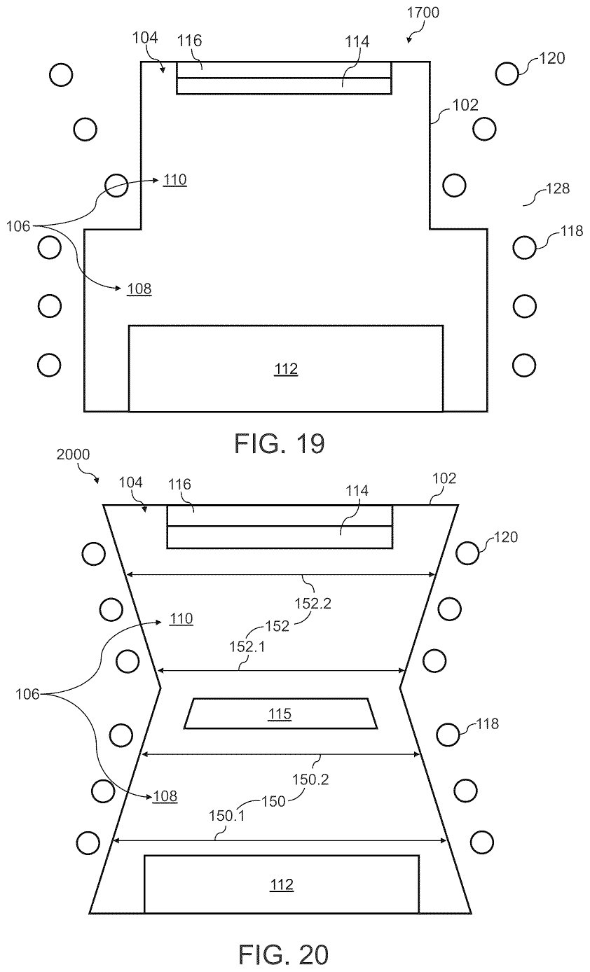

FIG. 19 is a cross-sectional schematic diagram of a crystal growth system 1900 adapted for use in a crystal growth process of the type contemplated by certain embodiments of the disclosure. Like the crystal growth systems of FIGS. 1 through 7 and 9 through 18, the crystal growth system 1900 of FIG. 19 includes the reaction crucible 102, the crystal growth chamber 104, the plurality of zones 106 including the first zone 108 and the second zone 110, the source material 112, the seed crystal 114, the seed holder 116, the first heater 118, and the second heater 120. The reaction crucible 102 may include the first diameter 142 and the second diameter 144 as discussed in relation to FIG. 13.

As depicted in FIG. 19, the second heater 120 may include a tapered coil such that a horizontal distance of the second heater 120 from the reaction crucible 102 is non-uniform along a vertical dimension of the reaction crucible 102. In some examples, such as the example depicted in FIG. 19, the tapered coil of the second heater 120 may include a horizontal distance from the reaction crucible 102 that is smaller with respect to a position on the second heater 120 nearest to the first zone 108. Similarly, the tapered coil of the second heater 120 may include a horizontal distance from the reaction crucible 102 that is larger with respect to a position on the second heater 120 nearest to the seed holder 116. Alternatively, in some examples, the tapered coil of the second heater 120 may include a horizontal distance from the reaction crucible 102 that is larger with respect to a position on the second heater 120 nearest to the seed holder 116.

The tapered coil of the second heater 120 may alter a temperature profile of processing profile of the second zone 110 such that the processing profile of the first zone 108 and the processing profile of the second zone 110 are not physically separated. It will be appreciated that the first heater 118 or the second heater 120 may have a tapered coil, and may be combined with any of the crystal growth systems contemplated by the present disclosure.

FIG. 20 is a cross-sectional schematic diagram of a crystal growth system 2000 adapted for use in a crystal growth process of the type contemplated by certain embodiments of the disclosure. Like the crystal growth systems of FIGS. 1 through 7 and 9 through 19, the crystal growth system 2000 of FIG. 20 includes the reaction crucible 102, the crystal growth chamber 104, the plurality of zones 106 including the first zone 108 and the second zone 110, the source material 112, the seed crystal 114, interface structure 115, the seed holder 116, the first heater 118, and the second heater 120.

The reaction crucible 102 may include a first non-uniform diameter 150 and a second non-uniform diameter 152. As depicted in FIG. 20, the first non-uniform diameter 150 may include the first zone 108. The first non-uniform diameter 150 may include a first diameter 150.1 that is larger than a second diameter 150.2 of the first non-uniform diameter 150, such that the first zone 108 is wider with respect to a volume nearest the source material 112 and gradually becomes more narrow with respect to a boundary with the second zone 110. Similarly, as depicted in FIG. 20, the second non-uniform diameter 152 may include the second zone 110. The second non-uniform diameter 152 may include a first diameter 152.1 that is larger than a second diameter 152.2 of the second non-uniform diameter 152, such that the second zone 110 is wider with respect to a volume nearest the seed holder 116 and gradually becomes more narrow with respect to a boundary with the first zone 108.

Altering the volume of the first zone 108 and/or the second zone 110 may provide more control over a temperature profile established in the crystal growth system 2000. Additionally, a larger volume of the first zone 108 may provide the crystal growth system 2000 a larger volume of the source material 112, such that larger crystals may be grown. As depicted in FIG. 20, the interface structure 115 may be positioned such that the interface structure is largely in a lower portion of the crystal growth chamber 104 (e.g., largely in the first zone 108). A sidewall of the interface structure may also be tapered to match the shape of a sidewall of the crucible in the first zone 108.

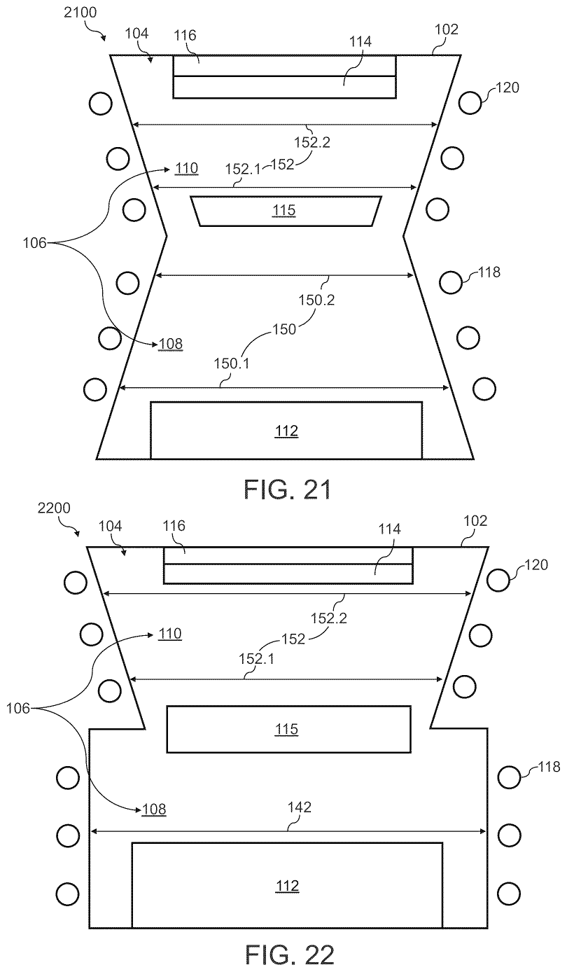

FIG. 21 is a cross-sectional schematic diagram of a crystal growth system 2100 adapted for use in a crystal growth process of the type contemplated by certain embodiments of the disclosure. Like the crystal growth systems of FIGS. 1 through 7 and 9 through 20, the crystal growth system 2100 of FIG. 21 includes the reaction crucible 102, the crystal growth chamber 104, the plurality of zones 106 including the first zone 108 and the second zone 110, the source material 112, the seed crystal 114, interface structure 115, the seed holder 116, the first heater 118, and the second heater 120.

The reaction crucible 102 may include the first non-uniform diameter 150 and the second non-uniform diameter 152. As depicted in FIG. 21, the first non-uniform diameter 150 may include the first zone 108. The first non-uniform diameter 150 may include the first diameter 150.1 that is larger than the second diameter 150.2 of the first non-uniform diameter 150, such that the first zone 108 is wider with respect to a volume nearest the source material 112 and gradually becomes more narrow with respect to a boundary with the second zone 110. Similarly, as depicted in FIG. 21, the second non-uniform diameter 152 may include the second zone 110. The second non-uniform diameter 152 may include the first diameter 152.1 that is larger than the second diameter 152.2 of the second non-uniform diameter 152, such that the second zone 110 is wider with respect to a volume nearest the seed holder 116 and gradually becomes more narrow with respect to a boundary with the first zone 108.

Altering the volume of the first zone 108 and/or the second zone 110 may provide more control over a temperature profile established in the crystal growth system 2100. Additionally, a larger volume of the first zone 108 may provide the crystal growth system 2100 a larger volume of the source material 112, such that larger crystals may be grown. As depicted in FIG. 21, the interface structure 115 may be positioned such that the interface structure is largely in an upper portion of the reaction chamber 102 (e.g., largely in the second zone 110). A sidewall of the interface structure 115 may also be tapered to match the shape of a sidewall of the crucible in the first zone 108.

FIG. 22 is a cross-sectional schematic diagram of a crystal growth system 2200 adapted for use in a crystal growth process of the type contemplated by certain embodiments of the disclosure. Like the crystal growth systems of FIGS. 1 through 7 and 9 through 21, the crystal growth system 2200 of FIG. 22 includes the reaction crucible 102, the crystal growth chamber 104, the plurality of zones 106 including the first zone 108 and the second zone 110, the source material 112, the seed crystal 114, interface structure 115, the seed holder 116, the first heater 118, and the second heater 120.

The reaction crucible 102 may include the first diameter 142 and the second non-uniform diameter 152. As depicted in FIG. 22, the first diameter 142 may be a uniform or continuous diameter. The first diameter may define the first zone 108. The second non-uniform diameter 152 may include the second zone 110. The second non-uniform diameter 152 may include the first diameter 152.1 that is larger than the second diameter 152.2 of the second non-uniform diameter 152, such that the second zone 110 is wider with respect to a volume nearest the seed holder 116 and gradually becomes more narrow with respect to a boundary with the first zone 108.

Altering the volume of the first zone 108 and/or the second zone 110 may provide more control over a temperature profile established in the crystal growth system 2200. Additionally, a larger volume of the first zone 108 may provide the crystal growth system 2200 a larger volume of the source material 112, such that larger crystals may be grown.

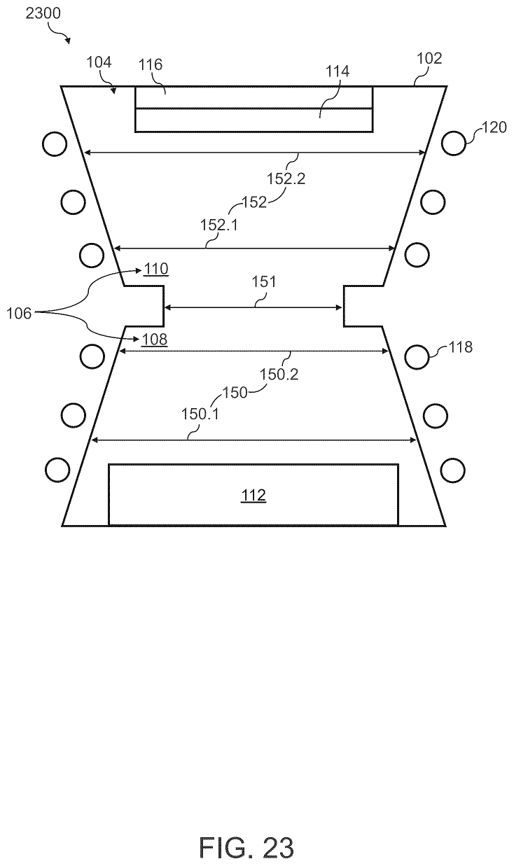

FIG. 23 is a cross-sectional schematic diagram of a crystal growth system 2300 adapted for use in a crystal growth process of the type contemplated by certain embodiments of the disclosure. Like the crystal growth systems of FIGS. 1 through 7 and 9 through 22, the crystal growth system 2300 of FIG. 23 includes the reaction crucible 102, the crystal growth chamber 104, the plurality of zones 106 including the first zone 108 and the second zone 110, the source material 112, the seed crystal 114, the seed holder 116, the first heater 118, and the second heater 120.

The reaction crucible 102 may include the first non-uniform diameter 150 and the second non-uniform diameter 152. As depicted in FIG. 23, the first non-uniform diameter 150 may include the first zone 108. The first non-uniform diameter 150 may include the first diameter 150.1 that is larger than the second diameter 150.2 of the first non-uniform diameter 150, such that the first zone 108 is wider with respect to a volume nearest the source material 112 and gradually becomes more narrow with respect to a boundary with the second zone 110. Similarly, as depicted in FIG. 23, the second non-uniform diameter 152 may include the second zone 110. The second non-uniform diameter 152 may include the first diameter 152.1 that is larger than the second diameter 152.2 of the second non-uniform diameter 152, such that the second zone 110 is wider with respect to a volume nearest the seed holder 116 and gradually becomes more narrow with respect to a boundary with the first zone 108. Further, the crystal growth system may include the first diameter 142, the first diameter 142 may be a uniform or continuous diameter between the first zone 108 and the second zone 110.

Altering the volume of the first zone 108 and/or the second zone 110 may provide more control over a temperature profile established in the crystal growth system 2300. Additionally, a larger volume of the first zone 108 may provide the crystal growth system 2300 a larger volume of the source material 112, such that larger crystals may be grown. The crystal growth system 2300 may include a portion with a smaller diameter 151 between the first zone 108 and the second zone 110. The sidewall of the crucible in this region may be considered an interface structure separating the first zone 108 and the second zone 110.

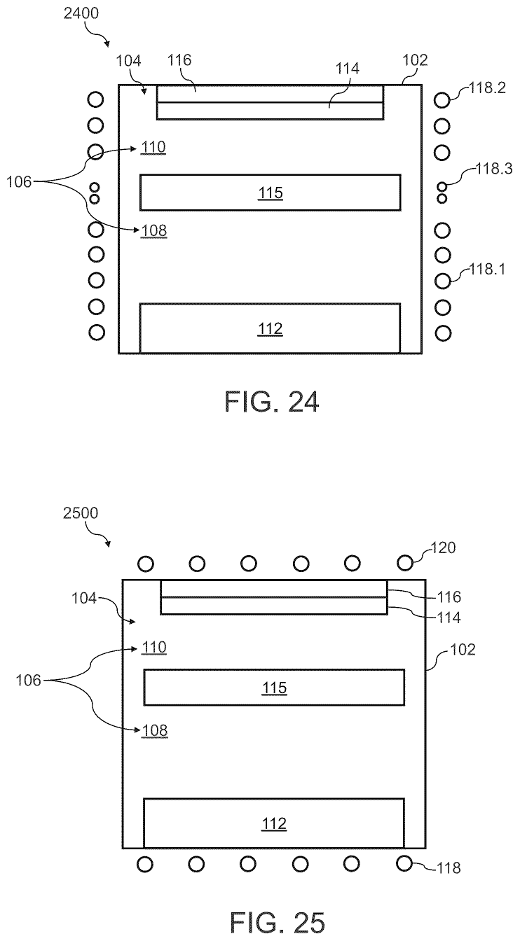

FIG. 24 is a cross-sectional schematic diagram of a crystal growth system 2400 adapted for use in a crystal growth process of the type contemplated by certain embodiments of the disclosure. Like the crystal growth systems of FIGS. 1 through 7 and 9 through 23, the crystal growth system 2400 of FIG. 24 includes the reaction crucible 102, the crystal growth chamber 104, the plurality of zones 106 including the first zone 108 and the second zone 110, the source material 112, the seed crystal 114, the interface structure 115, the seed holder 116, and a heater 118.

The heater 118 may be an inductive or resistive heater. The heater 118 may include different densities of coils or other elements at different portions of the reactor. For instance, the heater 118 may include a first portion 118.1 with a first coil density, a second portion 118.2 with a second coil density, and a third portion 118.3 with a third coil density. In some embodiments, the third coil density 118.3 may be greater than the first coil density 118.1 and/or the second coil density 118.2. The third coil density 118.3 may be at a location near the interface structure 115 to provide a localized hotspot on the interface structure 115 (e.g., to reduce deposition on the interface structure 115).

FIG. 25 is a cross-sectional schematic diagram of a crystal growth system 2500 adapted for use in a crystal growth process of the type contemplated by certain embodiments of the disclosure. Like the crystal growth systems of FIGS. 1 through 7 and 9 through 24, the crystal growth system 2500 of FIG. 25 includes the reaction crucible 102, the crystal growth chamber 104, the plurality of zones 106 including the first zone 108 and the second zone 110, the source material 112, the seed crystal 114, the interface structure 115, the seed holder 116, the first heater 118, and the second heater 120.

As depicted in FIG. 25, the first heater 118 may be configured to provide a temperature profile to the first zone 108 from a region below the source material 112. The first heater 118 may be positioned at a lowermost horizontal position of the reaction crucible 102. Similarly, the second heater 120 may be configured to provide a temperature profile to the second zone 110 from a region above the seed holder 116. The second heater 120 may be positioned at a uppermost horizontal position of the reaction crucible 102. By configuring the first heater 118 and the second heater 120 to provide thermal output at different portions of the crystal growth system 2500, more control over temperature profiles may be provided to the crystal growth system 2500.

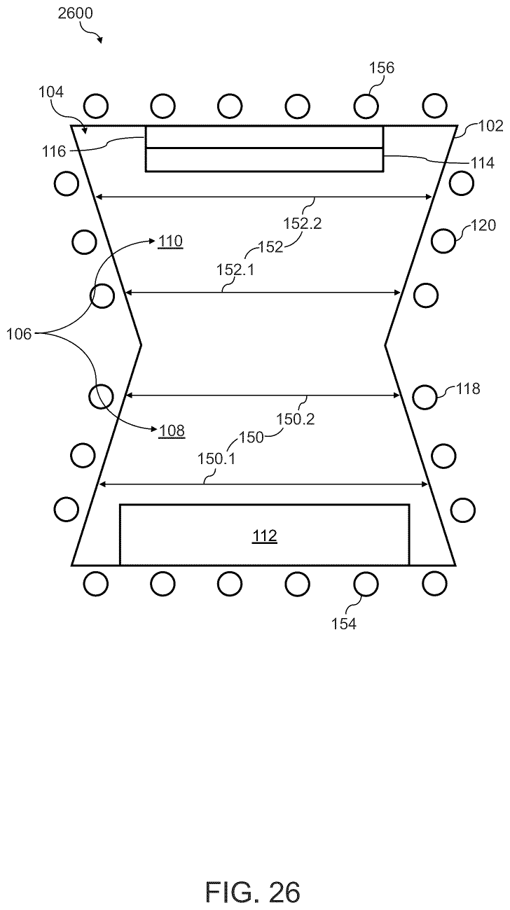

FIG. 26 is a cross-sectional schematic diagram of a crystal growth system 2600 adapted for use in a crystal growth process of the type contemplated by certain embodiments of the disclosure. Like the crystal growth systems of FIGS. 1 through 7 and 9 through 25, the crystal growth system 2600 of FIG. 26 includes the reaction crucible 102, the crystal growth chamber 104, the plurality of zones 106 including the first zone 108 and the second zone 110, the source material 112, the seed crystal 114, the seed holder 116, the first heater 118, and the second heater 120.

The reaction crucible 102 may include the first diameter 142 and the second non-uniform diameter 152. As depicted in FIG. 26, the first diameter 142 may be a uniform or continuous diameter. The first diameter may define the first zone 108. The second non-uniform diameter 152 may include the second zone 110. The second non-uniform diameter 152 may include the first diameter 152.1 that is larger than the second diameter 152.2 of the second non-uniform diameter 152, such that the second zone 110 is wider with respect to a volume nearest the seed holder 116 and gradually becomes more narrow with respect to a boundary with the first zone 108.

Altering the volume of the first zone 108 and/or the second zone 110 may provide more control over a temperature profile established in the crystal growth system 2600. Additionally, a larger volume of the first zone 108 may provide the crystal growth system 2600 a larger volume of the source material 112, such that larger crystals may be grown.

As depicted in FIG. 26, a third heater 154 may be configured to provide a temperature profile to the first zone 108 from a region below the source material 112. The is, the third heater 154 may be positioned at a lowermost horizontal position of the reaction crucible 102. Similarly, a fourth heater 156 may be configured to provide a temperature profile to the second zone 110 from a region above the seed holder 116. The is, the fourth heater 156 may be positioned at an uppermost horizontal position of the reaction crucible 102. By configuring the first heater 118, the second heater 120, the third heater 154 and the fourth heater 156 to provide thermal output at different portions of the crystal growth system 2600, more control over temperature profiles may be provided to the crystal growth system 2600.

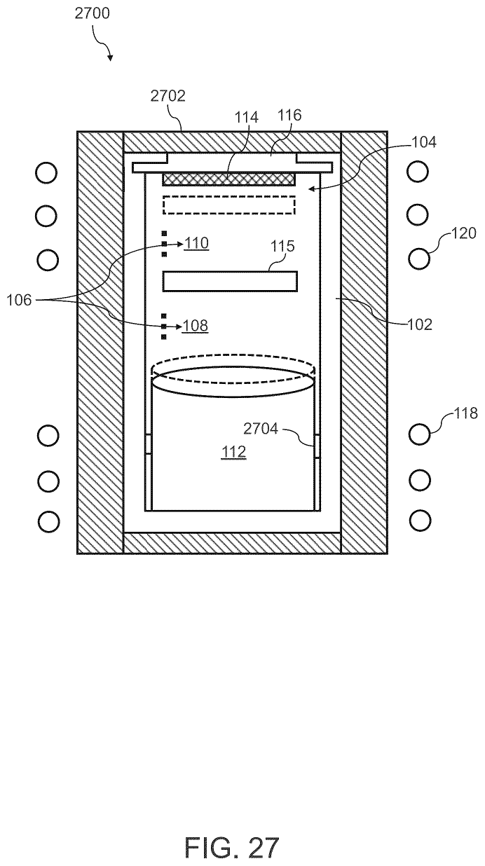

Aspects of the present disclosure may be used with any type of crystal growth system. Different crystal growth systems are provided in FIGS. 27-35 for purposes of illustration and discussion. Those of ordinary skill in the art, using the disclosures provided herein, will understand that aspects of the present disclosure may be used in any crystal growth system without deviating from the scope of the present disclosure.

FIG. 27 is a cross-sectional schematic diagram of a crystal growth system 2700 adapted for use in a crystal growth process of the type contemplated by certain embodiments of the disclosure. The crystal growth system 2700 includes the reaction crucible 102 (also referred to as a susceptor or growth cell), the interior of which defines the crystal growth chamber 104. The crystal growth system 2700 includes the first heater 118 and the second heater 120 adapted to heat the reaction crucible 102. Alternatively, a resistive heating approach may be applied to the heating of the reaction crucible 102. Using any competent heating mechanism and approach, the temperature within the crystal growth system 2700 may be controllable. The reaction crucible 102 may be, at least in part, a graphite structure. The crystal growth chamber 104 may include the plurality of zones 106, such as the first zone 108 and the second zone 110.

The crystal growth system 2700 may also include one or more gas inlet and gas outlet ports and associated equipment allowing the controlled introduction and evacuation of gas from an environment surrounding the reaction crucible 102. The introduction and evacuation of various gasses to or from the environment surrounding the reaction crucible 102 may be accomplished using a variety of inlets/outlets, pipes, valves, pumps, gas sources, and controllers. It will be further understood by those skilled in the art, using the disclosures provided herein, that the crystal growth system 2700 may further incorporate in certain embodiments a water-cooled quartz vessel.

The reaction crucible 102 may be surrounded by an insulation material 2702. The composition, size, and placement of the insulation material 2702 will vary with an individual crystal growth system, such as the crystal growth system 2700 of FIG. 27, to define and/or maintain desired temperature profile (e.g., both axially and radially) in relation to the reaction crucible 102.

Prior to establishment of the temperature profile, the reaction crucible 102 is loaded with a source material 112 (e.g., silicon carbide vapor source material, such as a silicon carbide powder or solid silicon carbide source). As such, the reaction crucible 102 includes one or more portions, at least one of which is capable of providing the source material 112. The source material 112 may be held in a lower portion of the reaction crucible 102, as is common for one type of crystal growth system, such as the crystal growth system 2700 of FIG. 27.

The seed crystal 114 may be placed above or in an upper portion of the reaction crucible 102. The seed crystal 114 may take the form of a silicon carbide seed wafer having a diameter, for instance, from about 50 mm to about 310 mm or greater. A silicon carbide crystal boule may be grown from the seed crystal 114 during a crystal growth process.

In the embodiment illustrated in FIG. 27, the seed holder 116 is used to hold the seed crystal 114. The seed holder 116 is securely attached to the reaction crucible 102 in an appropriate fashion. For example, in the orientation illustrated in FIG. 27, the seed holder 116 is attached to an uppermost portion of the reaction crucible 102 to hold the seed crystal 114 in a desired position. In some embodiments, the seed holder 116 is fabricated from carbon (e.g., graphite). The attachment of the seed crystal 114 (e.g., a seed wafer) to the seed holder 116 within the crystal growth system 2700 may be made, for instance, by a uniform thermal contact. Various techniques may be used to implement a uniform thermal contact. For example, the seed crystal 114 may be placed in direct physical contact with the seed holder 116, or an adhesive may be used to fix the seed crystal 114 to the seed holder 116, so as to provide uniform conductive and/or radiative heat transfer over substantially the entire area between the seed crystal 114 and the seed holder 116.

According to example aspects of the present disclosure, the crystal growth system 2700 may include the interface structure 115 that may be situated on the source material 112 or at any other location within the crystal growth system 2700, such as between the source material 112 and the seed crystal 114 as illustrated in FIG. 27. The interface structure 115 may provide a mechanism for transport of source vapor or other process gas during sublimation of the source material 112. The interface structure 115 may filter or otherwise reduce impurities from the source material 112 that may inadvertently sublimate in a crystal growth process. The interface structure 115 may provide for control of radiative heat transfer.

Further, the crystal growth system 2700 may optionally include the source material holder 2704. The source material holder 2704 may be, for example, one or more graphite components within the reaction crucible 102 that brace, support, or hold the source material 112. In some embodiments, the source material holder 2704 may be attached to the inner walls of the reaction crucible 102, as shown in FIG. 27.

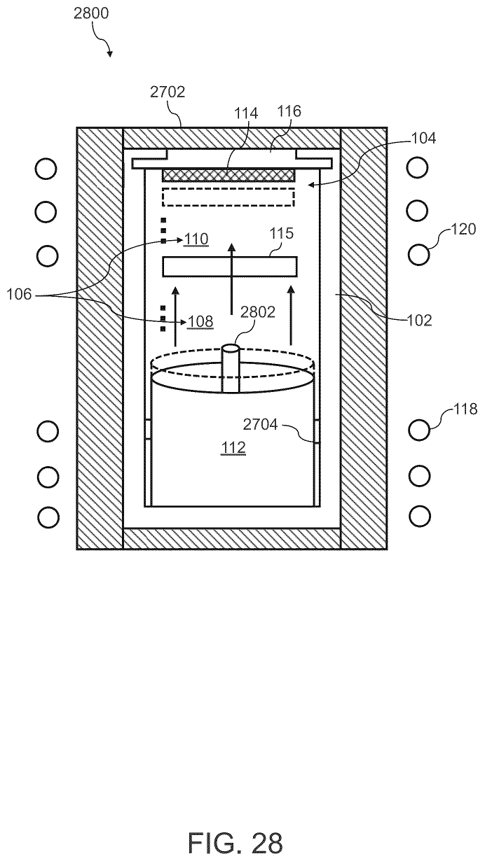

In one example embodiment, shown in FIG. 28, the crystal growth system 2800 may be similar to that shown in FIG. 27, but may also include an inlet 2802 for introducing a dopant (e.g., N₂) to the reaction crucible 102. The inlet 2802, may be, for example, a tube, pipe, vent, or the like. In some embodiments, the source material 112 may surround the inlet 2802. For example, in some embodiments, the source material 112 may include a channel through which the inlet 2802 is provided. In other embodiments, the source material 112 may include a plurality of subcomponents (attached or detached) which surround the inlet 2802. The inlet 2802 may be connected to a dopant-containing gas source (not shown) and configured to introduce the dopant-containing gas to the reaction crucible 102. An example of a dopant-containing gas is nitrogen.

The crystal growth system 2800 may include the interface structure 115 that may be situated within the reaction crucible 102. The interface structure 115 may provide a mechanism for the transport of source vapor during sublimation of the source material 112. The interface structure 115 may have any spatial orientation relative to the source material 112, the seed crystal 114, and/or the reaction crucible 102. The interface structure 115 may filter or otherwise reduce impurities from the source material 112 that may inadvertently sublimate in a crystal growth process. The interface structure 115 may provide for control of radiative heat transfer. The interface structure 115 may include any of the baffles discussed in relation to FIGS. 4A-44.

As shown in FIG. 28, the interface structure 115 may be located on the source material, may be spaced apart from the source material 112 and/or the seed crystal 114, or may be proximate to the seed crystal 114. In some embodiments, the system 2800 may include any number of interface structures 115 without deviating from the scope of the present disclosure. In some embodiments, the source material 112 may have the interface structure 115 or baffle element incorporated therein.

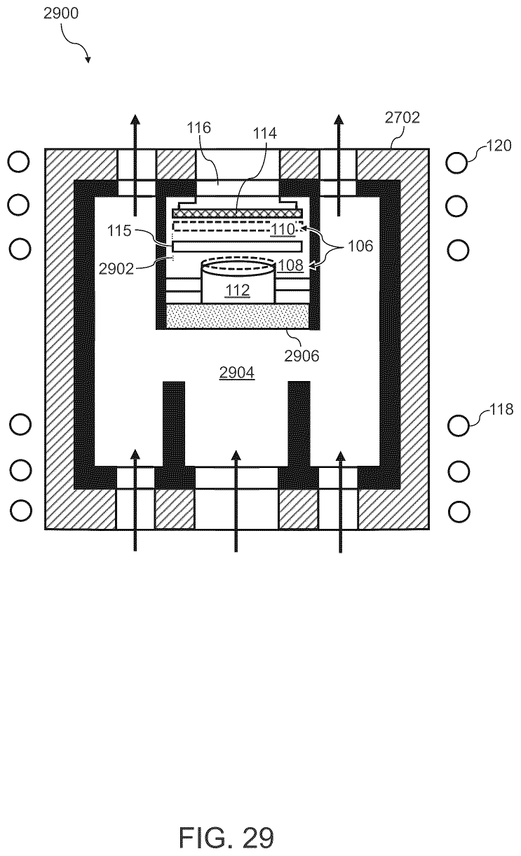

In another example embodiment, shown in FIG. 29, the crystal growth system 2900 may be a continuous feed PVT (CF-PVT) system. In a CF-PVT system, such as the crystal growth system 2900 of FIG. 29, the reaction crucible 102 may include an upper chamber 2902 and a lower chamber 2904. The upper chamber 2902 may include the source material 112 and the seed crystal 114. The upper chamber 2902 may include the plurality of zones 106, such as the first zone 108 and the second zone 110. The upper chamber 2902 may be separated from the lower chamber 2904 by a foamed structure 2906. The foamed structure 2906 may be formed, for example, from a gas-permeable graphite foam. The source material 112 may be placed on the foamed structure 2906 within the upper chamber 2902. A gaseous silicon source (e.g., trimethylsilane diluted in argon) may be supplied to the lower chamber 2904. As the gaseous silicon source is transported through the foamed structure 2906, it may react with a carbon source within the foamed structure 2906 (e.g., graphite) to form silicon carbide. A CF-PVT system, such as the crystal growth system 2900 of FIG. 29, combines a PVT process for the growth of single crystals and high temperature chemical vapor deposition (HTCVD) processes for the in-situ formation and continuous feeding of a high purity polycrystalline source. A CF-PVT system, such as the crystal growth system 2900 of FIG. 29, may be particularly useful for growing 3C silicon carbide.

The crystal growth system 2900 may include the interface structure 115 that may be situated within the upper chamber 2902 of the reaction crucible. The interface structure 115 may provide a mechanism for the transport of source vapor during sublimation of the source material 112. The interface structure 115 may filter or otherwise reduce impurities from the source material 112 that may inadvertently sublimate in a crystal growth process. The interface structure 115 may provide for control over radiative heat transfer. The interface structure 115 may have any spatial orientation relative to the source material 112, the seed crystal 114, and/or the upper chamber 2902 of the reaction crucible.

The first heater 118 may be positioned such that the first heater provides a temperature profile to the processing profile of the lower chamber 2904. The second heater 120 may be positioned such that the second heater provides a temperature profile to the processing profile of the upper chamber 2902 (e.g., the first zone 108 and the second zone 110).

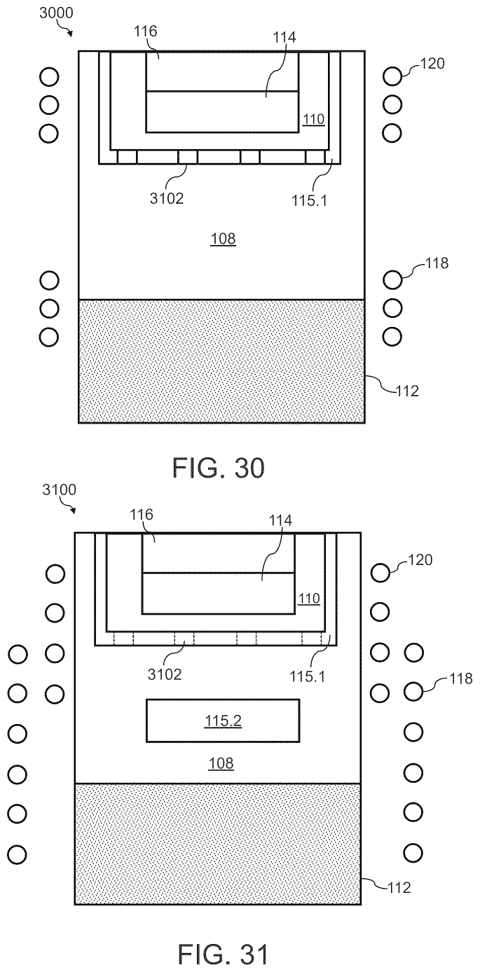

FIGS. 30 and 31 depict example crystal growth systems 3000 and 3100 according to example embodiments of the present disclosure. In FIG. 30, the crystal growth system 3000 includes the interface structure 115.1, the seed holder 116, the seed crystal 114, the crucible 412, and the source material 112. The interface structure 115 may be positioned such that the interface structure 115.1 extends around at least three sides of the seed crystal 114, with the longest dimension located below the seed crystal 114. The interface structure 115 may be referred to as a shell structure as it provides a shell around the seed crystal 114. The interface structure 115 may be graphite, such as porous graphite. The interface structure 115.1 may include one or more apertures 3102 that assist in the transport of source vapor from the source material 112 to the seed crystal 114.

In some examples, such as the example depicted in FIG. 31, the interface structure 115.1 may or may not include any apertures 3102. The interface structure 115.1 may be porous graphite and may have a porosity of greater than about 40%. The interface structure 115.1 may be positioned such that the interface structure 115.1 extends around at least three sides of the seed crystal 114, with the longest dimension located below the seed crystal 114. The system 3100 may include one or more second interface structures 115.2. The one or more second interface structures 115.2 may be arranged in the vapor transport path from the source material 112 to the seed crystal 114.

In either example depicted in FIGS. 30 and 31, the first zone 108 and the first heater 118 may be positioned in a lower portion of the reaction crucible 102 (e.g., below the interface structure 115.1 in proximity to the source material 112). The first heater 118 may be configured to provide a temperature profile to the processing profile of the first zone 108. Similarly, the second zone 110 and the second heater 120 may be positioned in an upper portion of the reaction crucible 102 (e.g., above the interface structure 115.2 in proximity to the seed crystal 114). The second heater 120 may be configured to provide a temperature profile to the processing profile of the second zone 110.

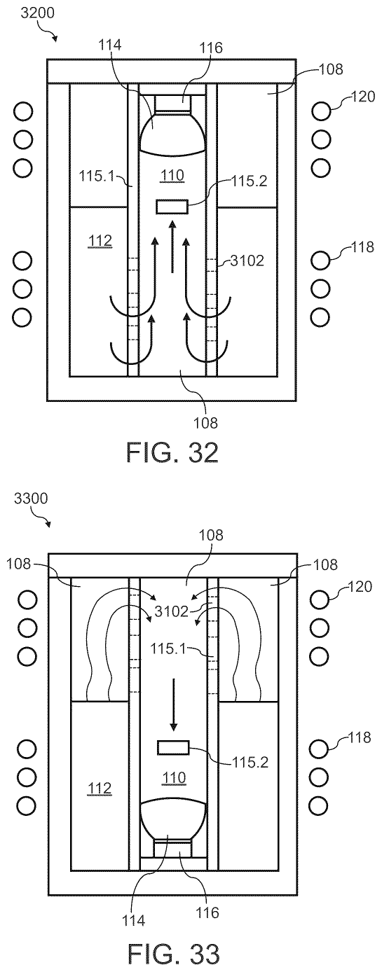

In FIG. 32, the crystal growth system 3200 includes the first interface structure 115.1, the second interface structure 115.2, the seed holder 116, the seed crystal 114, the reaction crucible 102, and the source material 112. The first interface structure 115.1 may include a tubular baffle structure. The seed crystal 114 may be within the first interface structure 115.1. The second interface structure 115.2 may separate a first zone 108 and a second zone 110. The first interface structure 115.1 or the second interface structure 115.2 may be graphite, such as porous graphite. The first interface structure 115.1 may include one or more apertures 3202 that assist in the transport of source vapor from the source material 112 to the seed crystal 114. The seed crystal 114 may be positioned at the top of the reaction crucible 102. The first interface structure 115.1 may or may not include apertures 3202.

FIG. 33 depicts a crystal growth system similar to that of FIG. 32. In FIG. 33, the tubular interface structure 115.1 may or may not include any apertures 3202. The system 3300 may further include one or more second interface structures 115.2. Source vapor may be transported through the first interface structure 115.1 or the second interface structure 115.2. The second interface structure may separate a first zone 108 and a second zone 110. The first interface structure 115.1 and/or the second interface structure 115.2 may reduce graphite inclusions or other impurities resulting from gravitational forces pulling impurities toward the seed crystal 114.

In either example depicted in FIGS. 32 and 33, the first heater 118 may be positioned in a lower portion of the reaction crucible 102. The first heater 118 may be configured to control a temperature profile to the first zone 108 in FIG. 32 and the second zone 110 in FIG. 33. Similarly, the second heater 120 may be positioned in an upper portion of the reaction crucible 102. The second heater 120 may be configured to control a temperature profile to the processing profile of the second zone 110 in FIG. 33 and the first zone 108 in FIG. 33.

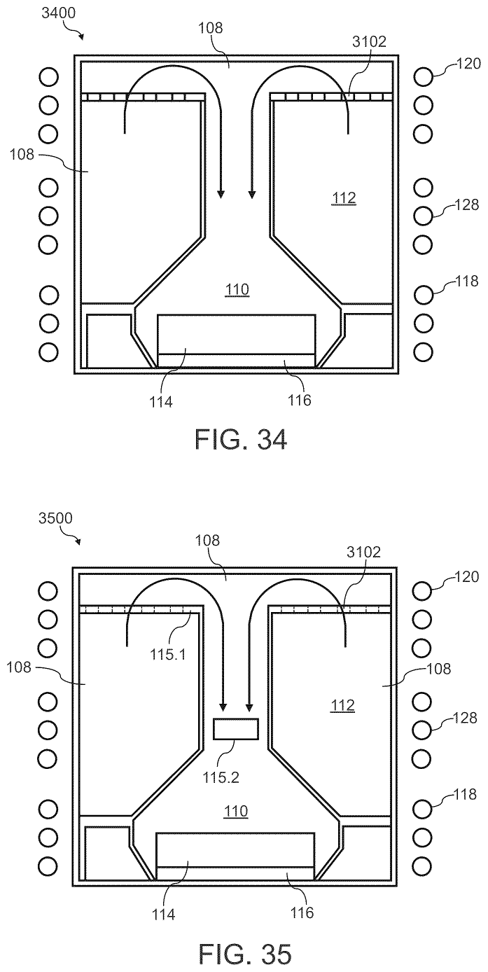

FIGS. 34 and 35 depict example crystal growth systems 3400 and 3500 according to example embodiments of the present disclosure. In FIG. 34, the crystal growth system 3400 includes the seed holder 116 and the seed crystal 114 arranged within the reaction crucible 102. The crucible 102 may have one or more angled sidewalls. The crystal growth system 3400 includes the source material 112. The interface structure 115.1 may be on top of the source material 112 and may separate the source material 112 from the reaction chamber defined by the crucible 102. As depicted in FIG. 34, the interface structure 115.1 may include one or more apertures 3202 to assist with vapor transport from the source material 112 to the seed crystal 114. The one or more apertures 3202 may have a shape and/or arrangement as any of the apertures provided herein.

FIG. 35 depicts a crystal growth system similar to that of FIG. 34. In FIG. 35, the first interface structure 115.1 may or may not include any apertures 3202. The system 3500 may further include a second interface structure 115.2. The second interface structure 115.2 may be in the transport path between the source material 112 and the seed crystal 114. Source vapor may be transported through the first interface structure 115.1 and/or the second interface structure 115.2 to the seed crystal 114. The interface structure 115.1 and/or the interface structure 115.2 may serve to reduce graphite inclusions or other impurities resulting from gravitational forces pulling impurities toward the seed crystal 114.

In either example depicted in FIGS. 34 and 35, the first heater 118 may be positioned in a lower portion of the reaction crucible 102. The first heater 118 may be configured to provide a temperature profile to the processing profile of the second zone 110. Similarly, the second heater 120 may be positioned in an upper portion of the reaction crucible 102. The second heater 120 may be configured to provide a temperature profile to the processing profile of the first zone 108. Similarly, the third heater 128 may be positioned between the first heater 118 and the second heater 120. The first heater 118, the second heater 120, and the third heater 128 may cumulatively contribute to a temperature profile to the second zone 110. The third heater 128 may be positioned about the interface structure 115.2

For any of the crystal growth systems provided herein, one or more parts of the crystal growth system or the source material may be 3D printed, such as disclosed in U.S. application Ser. No. 18/963,082, which is incorporated herein by reference. For instance, in some embodiments, the 3D printed source may include a silicon carbide powder and a binder (e.g., UV curable polymer adhesive). In some embodiments, the 3D printed part may include a ceramic material (e.g., silicon carbide, metal mixed with carbon, etc.) and a binder (e.g., UV curable polymer adhesive).

Example aspects of the present disclosure are set forth below. Any of the below features or examples may be used in combination with any of the embodiments or features provided in the present disclosure.

In an aspect, the present disclosure provides an example crystal growth system for growing crystalline material. In some implementations, the example crystal growth system includes a crucible at least partially defining a crystal growth chamber, the crystal growth chamber comprising a plurality of zones, each zone associated with a different processing profile. In some implementations, the example crystal growth system includes a silicon carbide crystal. In some implementations, the example crystal growth system includes a source material. In some implementations, the example crystal growth system includes an interface structure configured to separate at least two zones of the plurality of zones in the crystal growth system.

In some implementations of the example crystal growth system, the interface structure includes a baffle.

In some implementations of the example crystal growth system, the plurality of zones includes a first zone associated with a first processing profile and a second zone associated with a second processing profile.

In some implementations of the example crystal growth system, the first processing profile includes a first temperature profile, a first pressure, and a first vapor transport flux and the second processing profile includes a second temperature profile, a second pressure, and a second vapor transport flux.

In some implementations of the example crystal growth system, the first temperature profile is different from the second temperature profile.

In some implementations of the example crystal growth system, the first pressure is different from the second pressure.

In some implementations of the example crystal growth system, the first vapor transport flux is different from the second vapor transport flux.

In some implementations of the example crystal growth system, the crystal growth system includes a first heater for a first zone of the plurality of zones and a second heater for a second zone of the plurality of zones.

In some implementations of the example crystal growth system, at least a portion of the first heater overlaps with at least a portion of the second heater.

In some implementations of the example crystal growth system, the crystal growth system further includes a third heater between the first heater and the second heater, the third heater being disposed at a vertical location at least partially about the interface structure.

In some implementations of the example crystal growth system, at least one of first heater or the second heater includes a tapered coil.

In some implementations of the example crystal growth system, at least one of the first heater or the second heater has a non-uniform density of heat distribution elements.

In some implementations of the example crystal growth system, the one or more heat distribution elements include variations in material properties in the heat distribution elements or intentional design features to impede or enhance the transfer of thermal energy.

In some implementations of the example crystal growth system, the non-uniform density has a highest density of heat distribution elements at a point about the interface structure.

In some implementations of the example crystal growth system, at least one of the first heater or the second heater comprise a resistive heater or a radiofrequency heater.

In some implementations of the example crystal growth system, at least one of the first heater or the second heater is movable during a crystal growth process.

In some implementations of the example crystal growth system, the crystal growth system further includes one or more control devices, the one or more control devices operable to independently control the first heater and the second heater.

In some implementations of the example crystal growth system, the crystal growth system further includes at least one sensor, wherein the sensor may be positioned such that data is obtained in at least one of the first zone or the second zone.

In some implementations of the example crystal growth system, the crystal growth system further includes a sensor window positioned on the crucible.

In some implementations of the example crystal growth system, the sensor window includes quartz.

In some implementations of the example crystal growth system, the sensor is one or more of a pyrometer or a thermocouple.

In some implementations of the example crystal growth system, the controller is operable to independently control at least one of the first heater or the second heater based on data obtained from a sensor.

In some implementations of the example crystal growth system, at least one of the first heater or the second heater is operable at a fixed proportion of power delivery.

In some implementations of the example crystal growth system, the interface structure is at a location that is closer to the silicon carbide crystal relative to the source material.

In some implementations of the example crystal growth system, a first zone of the plurality of zones of the crystal growth chamber is associated with a first diameter and a second zone of the plurality of zones of the crystal growth chamber is associated with a second diameter, the first diameter being larger than the second diameter.

In some implementations of the example crystal growth system, the interface structure reduces a thermal interaction between two of the plurality of zones.

In some implementations of the example crystal growth system, the interface structure includes a graphite material.

In some implementations of the example crystal growth system, the interface structure includes a porous graphite material.

In some implementations of the example crystal growth system, the interface structure includes one or more apertures.

In some implementations of the example crystal growth system, the interface structure includes a coating.

In some implementations of the example crystal growth system, the coating is a patterned coating on a surface facing the silicon carbide crystal.

In some implementations of the example crystal growth system, the system further includes a ring crystallizer structure at least partially surrounding the silicon carbide crystal.

In some implementations of the example crystal growth system, the ring crystallizer structure includes a carbide material.

In some implementations of the example crystal growth system, the ring crystallizer structure includes tantalum carbide.

In some implementations of the example crystal growth system, the system further includes an insulator structure within the crucible at least partially surrounding the silicon carbide crystal.

In some implementations of the example crystal growth system, the insulator structure includes graphite.

In some implementations of the example crystal growth system, the insulator structure is tapered.

In some implementations of the example crystal growth system, the first heater and the second heater are configured to alter a temperature profile of at least a portion of the interface structure through cumulative heat production such that a localized hotspot is formed at the interface structure relative to a temperature profile of the silicon carbide crystal.

In some implementations of the example crystal growth system, the first heater extends vertically about the crucible from a point at which the interface structure is disposed in the crystal growth system to a region at or beyond a seed holder.

In some implementations of the example crystal growth system, the second heater extends vertically about the crucible from a point at which the interface structure is disposed in the crystal growth system to a region at or beyond the source material.

In some implementations of the example crystal growth system, the interface structure is positioned in a range of about 0.5 centimeters to about 10 centimeters from a seed holder.

In an aspect, the present disclosure provides an example crystal growth system for growing crystalline material. In some implementations, the example crystal growth system includes a crucible at least partially defining a crystal growth chamber, the crystal growth chamber comprising a first zone and a second zone. In some implementations, the example crystal growth system includes a source material in the first zone. In some implementations, the example crystal growth system includes a silicon carbide crystal in the second zone. In some implementations, the example crystal growth system includes an interface structure configured to separate the first zone and the second zone, the interface structure positioned at a location closer to the silicon carbide crystal relative to the source material.

In some implementations of the example crystal growth system, the interface structure is positioned such that a first vapor transport flux in the first zone is less than a second vapor transport flux in the second zone.

In some implementations of the example crystal growth system, the interface structure is positioned in a range of about 0.5 centimeters to about 10 centimeters from a seed holder.

In some implementations of the example crystal growth system, the interface structure includes a baffle.

In some implementations of the example crystal growth system, the first zone associated is with a first processing profile and the second zone is associated with a second processing profile.

In some implementations of the example crystal growth system, the first processing profile includes a first temperature profile, a first pressure, and a first vapor transport flux and the second processing profile includes a second temperature profile, a second pressure, and a second vapor transport flux.

In some implementations of the example crystal growth system, the first temperature profile is different from the second temperature profile.

In some implementations of the example crystal growth system, the first pressure is different from the second pressure.

In some implementations of the example crystal growth system, a first temperature profile is provided by a first heater about the first zone and a second temperature profile is provided by a second heater about the second zone.

In some implementations of the example crystal growth system, at least one of the first heater or the second heater has a non-uniform density of heat distribution elements.

In some implementations of the example crystal growth system, the one or more heat distribution elements include variations in material properties in the heat distribution elements or intentional design features to impede or enhance the transfer of thermal energy.

In some implementations of the example crystal growth system, the non-uniform density has a highest density of heat distribution elements at a point about the interface structure.

In some implementations of the example crystal growth system, at least one of the first heater or the second heater comprise a resistive heater or a radiofrequency heater.

In some implementations of the example crystal growth system, at least one of the first heater or the second heater is movable during a crystal growth process.

In some implementations of the example crystal growth system, the crystal growth system further includes one or more control devices, the one or more control devices operable to independently control the first heater and the second heater.

In some implementations of the example crystal growth system, the crystal growth system further includes at least one sensor, wherein the sensor may be positioned such that data is obtained in at least one of the first zone or the second zone.

In some implementations of the example crystal growth system, the crystal growth system further includes a sensor window positioned on the crucible.

In some implementations of the example crystal growth system, the sensor window includes quartz.

In some implementations of the example crystal growth system, the sensor is one or more of a pyrometer or a thermocouple.

In some implementations of the example crystal growth system, the controller is operable to independently control at least one of the first heater or the second heater based on data obtained from a sensor.

In some implementations of the example crystal growth system, at least one of the first heater or the second heater is operable at a fixed proportion of power delivery.

In some implementations of the example crystal growth system, a first zone of the crystal growth chamber is associated with a first diameter and a second zone of the crystal growth chamber is associated with a second diameter, the first diameter being larger than the second diameter.

In some implementations of the example crystal growth system, the interface structure reduces a thermal interaction between the first zone and the second zone.

In some implementations of the example crystal growth system, the interface structure includes a graphite material.

In some implementations of the example crystal growth system, the interface structure includes a porous graphite material.

In some implementations of the example crystal growth system, the interface structure includes one or more apertures.

In some implementations of the example crystal growth system, the interface structure includes a coating.

In some implementations of the example crystal growth system, the coating is a patterned coating on a surface facing the silicon carbide crystal.

In some implementations of the example crystal growth system, the system further includes a ring crystallizer structure at least partially surrounding the silicon carbide crystal.

In some implementations of the example crystal growth system, the ring crystallizer structure includes a carbide material.

In some implementations of the example crystal growth system, the ring crystallizer structure includes tantalum carbide.

In some implementations of the example crystal growth system, the system further includes an insulator structure within the crucible at least partially surrounding the silicon carbide crystal.

In some implementations of the example crystal growth system, the insulator structure includes graphite.

In an aspect, the present disclosure provides an example crystal growth system for growing crystalline material. In some implementations, the example crystal growth system includes a crucible at least partially defining a crystal growth chamber. In some implementations, the example crystal growth system includes a silicon carbide crystal. In some implementations, the example crystal growth system includes a source material. In some implementations, the example crystal growth system includes a first heater about the crucible. In some implementations, the example crystal growth system includes a second heater about the crucible. In some implementations, at least a portion of the first heater overlaps at least a portion of the second heater.

In some implementations of the example crystal growth system, at least one of first heater or the second heater includes a tapered coil.

In some implementations of the example crystal growth system, crystal growth system further includes an interface structure configured to partition the crystal growth chamber into a plurality of zones.

In some implementations of the example crystal growth system, the interface structure includes a baffle.

In some implementations of the example crystal growth system, the plurality of zones includes a first zone associated with a first processing profile and a second zone associated with a second processing profile.

In some implementations of the example crystal growth system, the first processing profile includes a first temperature profile, a first pressure, and a first vapor transport flux and the second processing profile includes a second temperature profile, a second pressure, and a second vapor transport flux.

In some implementations of the example crystal growth system, the first temperature profile is different from the second temperature profile.

In some implementations of the example crystal growth system, the first pressure is different from the second pressure.

In some implementations of the example crystal growth system, the first vapor transport flux is different from the second vapor transport flux.

In some implementations of the example crystal growth system, the first heater is positioned to alter a thermal gradient for the first zone of the plurality of zones and the second heater is positioned to alter a thermal gradient for the second zone of the plurality of zones.

In some implementations of the example crystal growth system, the portion of the first heater that overlaps with the portion of the second heater is configured to provide cumulative heat production such that a localized hotspot is formed.

In some implementations of the example crystal growth system, the crystal growth system further includes a third heater between the first heater and the second heater, the third heater being disposed at a vertical location at least partially about the interface structure.

In some implementations of the example crystal growth system, at least one of the first heater or the second heater has a non-uniform density of heat distribution elements.

In some implementations of the example crystal growth system, the one or more heat distribution elements include variations in material properties in the heat distribution elements or intentional design features to impede or enhance the transfer of thermal energy.

In some implementations of the example crystal growth system, the non-uniform density has a highest density of heat distribution elements at a point about the interface structure.

In some implementations of the example crystal growth system, at least one of the first heater or the second heater comprise a resistive heater.

In some implementations of the example crystal growth system, at least one of the first heater or the second heater is movable during a crystal growth process.

In some implementations of the example crystal growth system, the crystal growth system further includes one or more control devices, the one or more control devices operable to independently control the first heater and the second heater.

In some implementations of the example crystal growth system, the crystal growth system further includes at least one sensor, wherein the sensor may be positioned such that data is obtained in at least one of a first zone or a second zone.

In some implementations of the example crystal growth system, the crystal growth system further includes a sensor window positioned on the crucible.

In some implementations of the example crystal growth system, the sensor window includes quartz.

In some implementations of the example crystal growth system, the sensor is one or more of a pyrometer or a thermocouple.

In some implementations of the example crystal growth system, the controller is operable to independently control at least one of the first heater or the second heater based on data obtained from the sensor.

In some implementations of the example crystal growth system, at least one of the first heater or the second heater is operable at a fixed proportion of power delivery.

In some implementations of the example crystal growth system, the interface structure is at a location that is closer to the silicon carbide crystal relative to the source material.

In some implementations of the example crystal growth system, a first zone of the plurality of zones of the crystal growth chamber is associated with a first diameter and a second zone of the plurality of zones of the crystal growth chamber is associated with a second diameter, the first diameter being larger than the second diameter.

In some implementations of the example crystal growth system, the interface structure reduces a thermal interaction between two of the plurality of zones.

In some implementations of the example crystal growth system, the interface structure includes a graphite material.

In some implementations of the example crystal growth system, the interface structure includes a porous graphite material.

In some implementations of the example crystal growth system, the interface structure includes one or more apertures.

In some implementations of the example crystal growth system, the interface structure includes a coating.

In some implementations of the example crystal growth system, the coating is a patterned coating on a surface facing the silicon carbide crystal.

In some implementations of the example crystal growth system, the system further includes a ring crystallizer structure at least partially surrounding the silicon carbide crystal.

In some implementations of the example crystal growth system, the ring crystallizer structure includes a carbide material.

In some implementations of the example crystal growth system, the ring crystallizer structure includes tantalum carbide.

In some implementations of the example crystal growth system, the system further includes an insulator structure within the crucible at least partially surrounding the silicon carbide crystal.

In some implementations of the example crystal growth system, the insulator structure includes graphite.

In some implementations of the example crystal growth system, the insulator structure is tapered.

In some implementations of the example crystal growth system, the first heater and the second heater are configured to alter a temperature profile of at least a portion of the interface structure through cumulative heat production such that a localized hotspot is formed at the interface structure relative to a temperature profile of the silicon carbide crystal.

In some implementations of the example crystal growth system, the first heater extends vertically about the crucible from a point at which the interface structure is disposed in the crystal growth system to a region at or beyond a seed holder.

In some implementations of the example crystal growth system, the second heater extends vertically about the crucible from a point at which the interface structure is disposed in the crystal growth system to a region at or beyond the source material.

In an aspect, the present disclosure provides an example crystal growth system. In some implementations, the example crystal growth system includes a crucible at least partially defining a crystal growth chamber, the crystal growth chamber comprising a first zone and a second zone. In some implementations, the example crystal growth system includes a source material in the first zone. In some implementations, the example crystal growth system includes a silicon carbide crystal in the second zone. In some implementations, a diameter associated with the first zone is larger than a diameter associated with the second zone.

In some implementations of the example crystal growth system, the first zone is associated with a first processing profile and the second zone is associated with a second processing profile.

In some implementations of the example crystal growth system, the first processing profile includes a first temperature profile, a first pressure, and a first vapor transport flux and the second processing profile includes a second temperature profile, a second pressure, and a second vapor transport flux.

In some implementations of the example crystal growth system, the first temperature profile is different from the second temperature profile.

In some implementations of the example crystal growth system, the first pressure is different from the second pressure.

In some implementations of the example crystal growth system, the first vapor transport flux is different from the second vapor transport flux.

In some implementations of the example crystal growth system, crystal growth system further includes an interface structure configured to partition the crystal growth chamber into at least the first zone and the second zone.

In some implementations of the example crystal growth system, the interface structure is positioned in a range of about 0.5 centimeters to about 10 centimeters from a seed holder.

In some implementations of the example crystal growth system, the interface structure includes a baffle.

In some implementations of the example crystal growth system, the interface structure reduces a thermal interaction between the first zone and the second zone.

In some implementations of the example crystal growth system, the interface structure includes a graphite material.

In some implementations of the example crystal growth system, the interface structure includes a porous graphite material.

In some implementations of the example crystal growth system, the interface structure includes one or more apertures.

In some implementations of the example crystal growth system, the interface structure includes a coating.

In some implementations of the example crystal growth system, a first temperature profile is provided by a first heater about the first zone and a second temperature profile is provided by a second heater about the second zone.

In some implementations of the example crystal growth system, at least one of the first heater or the second heater has a non-uniform density of heat distribution elements.

In some implementations of the example crystal growth system, the one or more heat distribution elements include variations in material properties in the heat distribution elements or intentional design features to impede or enhance the transfer of thermal energy.

In some implementations of the example crystal growth system, the non-uniform density has a highest density of heat distribution elements at a point about an interface structure.

In some implementations of the example crystal growth system, at least one of the first heater or the second heater comprise a resistive heater or a radiofrequency heater.

In some implementations of the example crystal growth system, at least one of the first heater or the second heater is movable during a crystal growth process.

In some implementations of the example crystal growth system, the crystal growth system further includes one or more control devices, the one or more control devices operable to independently control the first heater and the second heater.

In some implementations of the example crystal growth system, the crystal growth system further includes at least one sensor, wherein the sensor may be positioned such that data is obtained in at least one of the first zone or the second zone.

In some implementations of the example crystal growth system, the crystal growth system further includes a sensor window positioned on the crucible.

In some implementations of the example crystal growth system, the sensor window includes quartz.

In some implementations of the example crystal growth system, the sensor is one or more of a pyrometer or a thermocouple.

In some implementations of the example crystal growth system, the controller is operable to independently control at least one of the first heater or the second heater based on data obtained from a sensor.

In some implementations of the example crystal growth system, at least one of the first heater or the second heater is operable at a fixed proportion of power delivery.

In some implementations of the example crystal growth system, the coating is a patterned coating on a surface facing the silicon carbide crystal.

In some implementations of the example crystal growth system, the crystal growth system includes a first heater for the first zone and a second heater for the second zone of crystal growth chamber.

In some implementations of the example crystal growth system, at least a portion of the first heater overlaps with at least a portion of the second heater.

In some implementations of the example crystal growth system, at least one of first heater or the second heater includes a tapered coil.

In some implementations of the example crystal growth system, the interface structure is at a location that is closer to the silicon carbide crystal relative to the source material.

In some implementations of the example crystal growth system, the crystal growth system further includes a heater disposed about the crucible at a point where the interface structure is positioned.

In some implementations of the example crystal growth system, the system further includes a ring crystallizer structure at least partially surrounding the silicon carbide crystal.

In some implementations of the example crystal growth system, the ring crystallizer structure includes a carbide material.

In some implementations of the example crystal growth system, the ring crystallizer structure includes tantalum carbide.

In some implementations of the example crystal growth system, the system further includes an insulator structure within the crucible at least partially surrounding the silicon carbide crystal.

In some implementations of the example crystal growth system, the insulator structure includes graphite.

In an aspect, the present disclosure provides an example crystal growth system. In some implementations, the example crystal growth system includes a crucible at least partially defining a crystal growth chamber. In some implementations, the example crystal growth system includes a silicon carbide crystal. In some implementations, the example crystal growth system includes a source material. In some implementations, the example crystal growth system includes a first heater about the crucible. In some implementations, the example crystal growth system includes a second heater about the crucible. In some implementations, the first heater and the second heater are configured to alter a temperature profile of at least a portion of the crucible through cumulative heat production.

In some implementations of the example crystal growth system, at least one of first heater or the second heater includes a tapered coil.

In some implementations of the example crystal growth system, crystal growth system further includes an interface structure configured to partition the crystal growth chamber into a plurality of zones.

In some implementations of the example crystal growth system, the interface structure includes a baffle.

In some implementations of the example crystal growth system, the interface structure is positioned in a range of about 0.5 centimeters to about 10 centimeters from a seed holder.

In some implementations of the example crystal growth system, the plurality of zones includes a first zone associated with a first processing profile and a second zone associated with a second processing profile.

In some implementations of the example crystal growth system, the first processing profile includes a first temperature profile, a first pressure, and a first vapor transport flux and the second processing profile includes a second temperature profile, a second pressure, and a second vapor transport flux.

In some implementations of the example crystal growth system, the first temperature profile is different from the second temperature profile.

In some implementations of the example crystal growth system, the first pressure is different from the second pressure.

In some implementations of the example crystal growth system, the first vapor transport flux is different from the second vapor transport flux.

In some implementations of the example crystal growth system, the first heater is positioned to alter a thermal gradient for the first zone of the plurality of zones and the second heater is positioned to alter a thermal gradient for the second zone of the plurality of zones.

In some implementations of the example crystal growth system, a first temperature profile is provided by a first heater about the first zone and a second temperature profile is provided by a second heater about the second zone.

In some implementations of the example crystal growth system, at least one of the first heater or the second heater has a non-uniform density of heat distribution elements.

In some implementations of the example crystal growth system, the one or more heat distribution elements include variations in material properties in the heat distribution elements or intentional design features to impede or enhance the transfer of thermal energy.

In some implementations of the example crystal growth system, the non-uniform density has a highest density of heat distribution elements at a point about the interface structure.

In some implementations of the example crystal growth system, at least one of the first heater or the second heater comprise a resistive heater or a radiofrequency heater.

In some implementations of the example crystal growth system, at least one of the first heater or the second heater is movable during a crystal growth process.

In some implementations of the example crystal growth system, the crystal growth system further includes one or more control devices, the one or more control devices operable to independently control the first heater and the second heater.

In some implementations of the example crystal growth system, the crystal growth system further includes at least one sensor, wherein the sensor may be positioned such that data is obtained in at least one of a first zone or a second zone.

In some implementations of the example crystal growth system, the crystal growth system further includes a sensor window positioned on the crucible.

In some implementations of the example crystal growth system, the sensor window includes quartz.

In some implementations of the example crystal growth system, the sensor is one or more of a pyrometer or a thermocouple.

In some implementations of the example crystal growth system, the controller is operable to independently control at least one of the first heater or the second heater based on data obtained from the sensor.

In some implementations of the example crystal growth system, at least one of the first heater or the second heater is operable at a fixed proportion of power delivery.

In some implementations of the example crystal growth system, the interface structure is at a location that is closer to the silicon carbide crystal relative to the source material.

In some implementations of the example crystal growth system, a first zone of the plurality of zones of the crystal growth chamber is associated with a first diameter and a second zone of the plurality of zones of the crystal growth chamber is associated with a second diameter, the first diameter being larger than the second diameter.

In some implementations of the example crystal growth system, the interface structure reduces a thermal interaction between two of the plurality of zones.

In some implementations of the example crystal growth system, the interface structure includes a graphite material.

In some implementations of the example crystal growth system, the interface structure includes a porous graphite material.

In some implementations of the example crystal growth system, the interface structure includes one or more apertures.

In some implementations of the example crystal growth system, the interface structure includes a coating.

In some implementations of the example crystal growth system, the coating is a patterned coating on a surface facing the silicon carbide crystal.

In some implementations of the example crystal growth system, the system further includes a ring crystallizer structure at least partially surrounding the silicon carbide crystal.

In some implementations of the example crystal growth system, the ring crystallizer structure includes a carbide material.

In some implementations of the example crystal growth system, the ring crystallizer structure includes tantalum carbide.

In some implementations of the example crystal growth system, the system further includes an insulator structure within the crucible at least partially surrounding the silicon carbide crystal

In some implementations of the example crystal growth system, the insulator structure includes graphite.

In some implementations of the example crystal growth system, the insulator structure is tapered.

In an aspect, the present disclosure provides an example crystal growth system. In some implementations, the example crystal growth system includes a crucible at least partially defining a crystal growth chamber, the crystal growth chamber including a plurality of zones, each zone associated with a different processing profile. In some implementations, the example crystal growth system includes a silicon carbide crystal. In some implementations, the example crystal growth system includes a source material. In some implementations, the example crystal growth system includes a first heater about the crucible. In some implementations, the example crystal growth system includes a second heater about the crucible. In some implementations, the first heater and the second heater are configured to alter a temperature profile of at least a portion of the crucible through cumulative heat production such that a localized hotspot is formed at the interface structure relative to a temperature profile of the silicon carbide crystal.

In some implementations of the example crystal growth system, the interface structure includes a baffle.

In some implementations of the example crystal growth system, the plurality of zones includes a first zone associated with a first processing profile and a second zone associated with a second processing profile.

In some implementations of the example crystal growth system, the first processing profile includes a first temperature profile, a first pressure, and a first vapor transport flux and the second processing profile includes a second temperature profile, a second pressure, and a second vapor transport flux.

In some implementations of the example crystal growth system, the first temperature profile is different from the second temperature profile.

In some implementations of the example crystal growth system, the first pressure is different from the second pressure.

In some implementations of the example crystal growth system, the first vapor transport flux is different from the second vapor transport flux.

In some implementations of the example crystal growth system, at least one of first heater or the second heater includes a tapered coil.

In some implementations of the example crystal growth system, at least one of the first heater or the second heater has a non-uniform density of heat distribution elements.

In some implementations of the example crystal growth system, the one or more heat distribution elements include variations in material properties in the heat distribution elements or intentional design features to impede or enhance the transfer of thermal energy.

In some implementations of the example crystal growth system, the non-uniform density has a highest density of heat distribution elements at a point about the interface structure.

In some implementations of the example crystal growth system, at least one of the first heater or the second heater comprise a resistive heater or a radiofrequency heater.

In some implementations of the example crystal growth system, at least one of the first heater or the second heater is movable during a crystal growth process.

In some implementations of the example crystal growth system, the crystal growth system further includes one or more control devices, the one or more control devices operable to independently control the first heater and the second heater.

In some implementations of the example crystal growth system, the crystal growth system further includes at least one sensor, wherein the sensor may be positioned such that data is obtained in at least one of a first zone or a second zone.

In some implementations of the example crystal growth system, the crystal growth system further includes a sensor window positioned on the crucible.

In some implementations of the example crystal growth system, the sensor window includes quartz.

In some implementations of the example crystal growth system, the sensor is one or more of a pyrometer or a thermocouple.

In some implementations of the example crystal growth system, the controller is operable to independently control at least one of the first heater or the second heater based on data obtained from the sensor.

In some implementations of the example crystal growth system, at least one of the first heater or the second heater is operable at a fixed proportion of power delivery.

In some implementations of the example crystal growth system, the interface structure is at a location that is closer to the silicon carbide crystal relative to the source material.

In some implementations of the example crystal growth system, the interface structure is positioned in a range of about 0.5 centimeters to about 10 centimeters from a seed holder.

In some implementations of the example crystal growth system, a first zone of the plurality of zones of the crystal growth chamber is associated with a first diameter and a second zone of the plurality of zones of the crystal growth chamber is associated with a second diameter, the first diameter being larger than the second diameter.

In some implementations of the example crystal growth system, the interface structure reduces a thermal interaction between two of the plurality of zones.

In some implementations of the example crystal growth system, the interface structure includes a graphite material.

In some implementations of the example crystal growth system, the interface structure includes a porous graphite material.

In some implementations of the example crystal growth system, the interface structure includes one or more apertures.

In some implementations of the example crystal growth system, the interface structure includes a coating.

In some implementations of the example crystal growth system, the coating is a patterned coating on a surface facing the silicon carbide crystal.

In some implementations of the example crystal growth system, the system further includes a ring crystallizer structure at least partially surrounding the silicon carbide crystal.

In some implementations of the example crystal growth system, the ring crystallizer structure includes a carbide material.

In some implementations of the example crystal growth system, the ring crystallizer structure includes tantalum carbide.

In some implementations of the example crystal growth system, the system further includes an insulator structure within the crucible at least partially surrounding the silicon carbide crystal.

In some implementations of the example crystal growth system, the insulator structure includes graphite.

In an aspect, the present disclosure provides an example crystal growth system. In some implementations, the example crystal growth system includes a crucible at least partially defining a crystal growth chamber, the crystal growth chamber including a plurality of zones, each zone associated with a different processing profile. In some implementations, the example crystal growth system includes a silicon carbide crystal. In some implementations, the example crystal growth system includes a source material. In some implementations, the example crystal growth system includes an interface structure configured to separate at least two zones of the plurality of zones in the crystal growth system. In some implementations, the example crystal growth system includes a first heater about the crucible, wherein the first heater extends vertically about the crucible from a point at which the interface structure is disposed in the crystal growth system to a region at or beyond a seed holder. In some implementations, the example crystal growth system includes a second heater about the crucible, wherein the second heater extends vertically about the crucible from a point at which the interface structure is disposed in the crystal growth system to a region at or beyond the source material.

In some implementations of the example crystal growth system, the interface structure includes a baffle.

In some implementations of the example crystal growth system, the plurality of zones includes a first zone associated with a first processing profile and a second zone associated with a second processing profile.

In some implementations of the example crystal growth system, the first processing profile includes a first temperature profile, a first pressure, and a first vapor transport flux and the second processing profile includes a second temperature profile, a second pressure, and a second vapor transport flux.

In some implementations of the example crystal growth system, the first temperature profile is different from the second temperature profile.

In some implementations of the example crystal growth system, the first pressure is different from the second pressure.

In some implementations of the example crystal growth system, the first vapor transport flux is different from the second vapor transport flux.

In some implementations of the example crystal growth system, at least one of first heater or the second heater includes a tapered coil.

In some implementations of the example crystal growth system, at least one of the first heater or the second heater has a non-uniform density of heat distribution elements.

In some implementations of the example crystal growth system, the one or more heat distribution elements include variations in material properties in the heat distribution elements or intentional design features to impede or enhance the transfer of thermal energy.

In some implementations of the example crystal growth system, the non-uniform density has a highest density of heat distribution elements at a point about the interface structure.

In some implementations of the example crystal growth system, at least one of the first heater or the second heater comprise a resistive heater or a radiofrequency heater.

In some implementations of the example crystal growth system, at least one of the first heater or the second heater is movable during a crystal growth process.

In some implementations of the example crystal growth system, the crystal growth system further includes one or more control devices, the one or more control devices operable to independently control the first heater and the second heater.

In some implementations of the example crystal growth system, the crystal growth system further includes at least one sensor, wherein the sensor may be positioned such that data is obtained in at least one of a first zone or a second zone.

In some implementations of the example crystal growth system, the crystal growth system further includes a sensor window positioned on the crucible.

In some implementations of the example crystal growth system, the sensor window includes quartz.

In some implementations of the example crystal growth system, the sensor is one or more of a pyrometer or a thermocouple.

In some implementations of the example crystal growth system, the controller is operable to independently control at least one of the first heater or the second heater based on data obtained from the sensor.

In some implementations of the example crystal growth system, at least one of the first heater or the second heater is operable at a fixed proportion of power delivery.

In some implementations of the example crystal growth system, the interface structure is at a location that is closer to the silicon carbide crystal relative to the source material.

In some implementations of the example crystal growth system, the interface structure is positioned in a range of about centimeter to about 10 centimeters from the seed holder.

In some implementations of the example crystal growth system, a first zone of the plurality of zones of the crystal growth chamber is associated with a first diameter and a second zone of the plurality of zones of the crystal growth chamber is associated with a second diameter, the first diameter being larger than the second diameter.

In some implementations of the example crystal growth system, the interface structure reduces a thermal interaction between two of the plurality of zones.

In some implementations of the example crystal growth system, the interface structure includes a graphite material.

In some implementations of the example crystal growth system, the interface structure includes a porous graphite material.

In some implementations of the example crystal growth system, the interface structure includes one or more apertures.

In some implementations of the example crystal growth system, the interface structure includes a coating.

In some implementations of the example crystal growth system, the coating is a patterned coating on a surface facing the silicon carbide crystal.

In some implementations of the example crystal growth system, the system further includes a ring crystallizer structure at least partially surrounding the silicon carbide crystal.

In some implementations of the example crystal growth system, the ring crystallizer structure includes a carbide material.

In some implementations of the example crystal growth system, the ring crystallizer structure includes tantalum carbide.

In some implementations of the example crystal growth system, the system further includes an insulator structure within the crucible at least partially surrounding the silicon carbide crystal.

In some implementations of the example crystal growth system, the insulator structure includes graphite.

In some implementations of the example crystal growth system, the insulator structure is tapered.

In an aspect, the present disclosure provides an example crystal growth system. In some implementations, the example crystal growth system includes a crucible at least partially defining a crystal growth chamber, the crystal growth chamber including a plurality of zones, each zone associated with a different processing profile. In some implementations, the example crystal growth system includes a silicon carbide crystal. In some implementations, the example crystal growth system includes a source material. In some implementations, the example crystal growth system includes an interface structure configured to separate at least two zones of the plurality of zones in the crystal growth system. In some implementations, the example crystal growth system includes at least one heater about the crucible, wherein the heater is disposed about the crucible such that the heater overlaps with a point at which the interface structure is disposed in the crystal growth system.

In some implementations of the example crystal growth system, at least one heater fully encompasses a circumference of the crucible, such that even heat distribution is provided around a contour of the crucible.

In some implementations of the example crystal growth system, the at least one heater does not extend in a vertical direction beyond the point at which the interface structure is disposed within the crystal growth system.

In some implementations of the example crystal growth system, the interface structure includes a baffle.

In some implementations of the example crystal growth system, the plurality of zones includes a first zone associated with a first processing profile and a second zone associated with a second processing profile.

In some implementations of the example crystal growth system, the first processing profile includes a first temperature profile, a first pressure, and a first vapor transport flux and the second processing profile includes a second temperature profile, a second pressure, and a second vapor transport flux.

In some implementations of the example crystal growth system, the first temperature profile is different from the second temperature profile.

In some implementations of the example crystal growth system, the first pressure is different from the second pressure.

In some implementations of the example crystal growth system, the first vapor transport flux is different from the second vapor transport flux.

In some implementations of the example crystal growth system, the interface structure is at a location that is closer to the silicon carbide crystal relative to the source material.

In some implementations of the example crystal growth system, the interface structure is positioned in a range of about 0.5 centimeter to about 10 centimeters from a seed holder.

In some implementations of the example crystal growth system, a first zone of the plurality of zones of the crystal growth chamber is associated with a first diameter and a second zone of the plurality of zones of the crystal growth chamber is associated with a second diameter, the first diameter being larger than the second diameter.

In some implementations of the example crystal growth system, the interface structure reduces a thermal interaction between two of the plurality of zones.

In some implementations of the example crystal growth system, the interface structure includes a graphite material.

In some implementations of the example crystal growth system, the interface structure includes a porous graphite material.

In some implementations of the example crystal growth system, the interface structure includes one or more apertures.

In some implementations of the example crystal growth system, the interface structure includes a coating.

In some implementations of the example crystal growth system, the coating is a patterned coating on a surface facing the silicon carbide crystal.

In some implementations of the example crystal growth system, the system further includes a ring crystallizer structure at least partially surrounding the silicon carbide crystal.

In some implementations of the example crystal growth system, the ring crystallizer structure includes a carbide material.

In some implementations of the example crystal growth system, the ring crystallizer structure includes tantalum carbide.

In some implementations of the example crystal growth system, the system further includes an insulator structure within the crucible at least partially surrounding the silicon carbide crystal

In some implementations of the example crystal growth system, the insulator structure includes graphite.

In some implementations of the example crystal growth system, the insulator structure is tapered.

In some implementations of the example crystal growth system, the crystal growth system includes a first heater for a first zone of the plurality of zones and a second heater for a second zone of the plurality of zones of the crystal growth chamber.

In some implementations of the example crystal growth system, at least a portion of the first heater overlaps with at least a portion of the second heater.

In some implementations of the example crystal growth system, at least one of first heater or the second heater includes a tapered coil.

In some implementations of the example crystal growth system, at least one of the first heater or the second heater has a non-uniform density of heat distribution elements.

In some implementations of the example crystal growth system, the one or more heat distribution elements include variations in material properties in the heat distribution elements or intentional design features to impede or enhance the transfer of thermal energy.

In some implementations of the example crystal growth system, the non-uniform density has a highest density of heat distribution elements at a point about the interface structure.

In some implementations of the example crystal growth system, at least one of the first heater or the second heater comprise a resistive heater or a radio frequency heater.

In some implementations of the example crystal growth system, at least one of the first heater or the second heater is movable during a crystal growth process.

In some implementations of the example crystal growth system, the crystal growth system further includes one or more control devices, the one or more control devices operable to independently control the first heater and the second heater.

In some implementations of the example crystal growth system, the crystal growth system further includes at least one sensor, wherein the sensor may be positioned such that data is obtained in at least one of a first zone or a second zone.

In some implementations of the example crystal growth system, the crystal growth system further includes a sensor window positioned on the crucible.

In some implementations of the example crystal growth system, the sensor window includes quartz.

In some implementations of the example crystal growth system, the sensor is one or more of a pyrometer or a thermocouple.

In some implementations of the example crystal growth system, the controller is operable to independently control at least one of the first heater or the second heater based on data obtained from the sensor.

In some implementations of the example crystal growth system, at least one of the first heater or the second heater is operable at a fixed proportion of power delivery.

In an aspect, the present disclosure provides an example crystal growth system. In some implementations, the example crystal growth system includes a crucible at least partially defining a crystal growth chamber, the crystal growth chamber including a plurality of zones, each zone associated with a different processing profile. In some implementations, the example crystal growth system includes a silicon carbide crystal. In some implementations, the example crystal growth system includes a source material. In some implementations, the example crystal growth system includes an interface structure configured to separate at least two zones of the plurality of zones in the crystal growth system. In some implementations, the example crystal growth system includes a first heater about the crucible, wherein the first heater is disposed about the crucible such that the first heater provides a first heat distribution to the first zone. In some implementations, the example crystal growth system includes a second heater about the crucible, wherein the second heater is disposed about the crucible such that the second heater provides a second heat distribution to the second zone. In some implementations, the example crystal growth system includes a third heater about the crucible, wherein the third heater is disposed about the crucible such that third heater overlaps with a point at which the interface structure is disposed in the crystal growth system, the third heater configured to provide a third heat distribution to a region closest in proximity to the interface structure.

In some implementations of the example crystal growth system, at least one of the first heater, the second heater, or the third heater have a non-uniform density of heat distribution elements.

In some implementations of the example crystal growth system, the one or more heat distribution elements include variations in material properties in the heat distribution elements or intentional design features to impede or enhance the transfer of thermal energy.

In some implementations of the example crystal growth system, the non-uniform density has a highest density of heat distribution elements at a point about the interface structure.

In some implementations of the example crystal growth system, at least one of the first heater, the second heater, or the third heater comprise a resistive heater.

In some implementations of the example crystal growth system, at least one of the first heater, the second heater, or the third heater comprise an RF heater.

In some implementations of the example crystal growth system, the crystal growth system further includes one or more control devices, the one or more control devices operable to independently control the first heater and the second heater.

In some implementations of the example crystal growth system, the crystal growth system further includes at least one sensor, wherein the sensor may be positioned such that data is obtained in at least one of a first zone or a second zone.

In some implementations of the example crystal growth system, the crystal growth system further includes a sensor window positioned on the crucible.

In some implementations of the example crystal growth system, the sensor window includes quartz.

In some implementations of the example crystal growth system, the sensor is one or more of a pyrometer or a thermocouple.

In some implementations of the example crystal growth system, the controller is operable to independently control at least one of the first heater or the second heater based on data obtained from the sensor.

In some implementations of the example crystal growth system, at least one of the first heater, the second heater, or the third heater is operable at a fixed proportion of power delivery.

In some implementations of the example crystal growth system, the interface structure includes a baffle.

In some implementations of the example crystal growth system, the first processing profile includes a first temperature profile, a first pressure, and a first vapor transport flux and the second processing profile includes a second temperature profile, a second pressure, and a second vapor transport flux.

In some implementations of the example crystal growth system, the first temperature profile is different from the second temperature profile.

In some implementations of the example crystal growth system, the first pressure is different from the second pressure.

In some implementations of the example crystal growth system, the first vapor transport flux is different from the second vapor transport flux.

In some implementations of the example crystal growth system, at least one of the first heater or the second heater includes a tapered coil.

In some implementations of the example crystal growth system, the interface structure is at a location that is closer to the silicon carbide crystal relative to the source material.

In some implementations of the example crystal growth system, a first zone of the crystal growth chamber is associated with a first diameter and a second zone of the crystal growth chamber is associated with a second diameter, the first diameter being larger than the second diameter.

In some implementations of the example crystal growth system, the interface structure reduces a thermal interaction between the first zone and the second zone.

In some implementations of the example crystal growth system, the interface structure includes a graphite material.

In some implementations of the example crystal growth system, the interface structure includes a porous graphite material.

In some implementations of the example crystal growth system, the interface structure includes one or more apertures.

In some implementations of the example crystal growth system, the interface structure includes a coating.

In some implementations of the example crystal growth system, the coating is a patterned coating on a surface facing the silicon carbide crystal.

In some implementations of the example crystal growth system, the system further includes a ring crystallizer structure at least partially surrounding the silicon carbide crystal

In some implementations of the example crystal growth system, the ring crystallizer structure includes a carbide material.

In some implementations of the example crystal growth system, the ring crystallizer structure includes tantalum carbide.

In some implementations of the example crystal growth system, the system further includes an insulator structure within the crucible at least partially surrounding the silicon carbide crystal.

In some implementations of the example crystal growth system, the insulator structure includes graphite.

In some implementations of the example crystal growth system, the insulator structure is tapered.

In some implementations of the example crystal growth system, the interface structure is positioned in a range of about 0.5 centimeter to about 10 centimeters from the silicon carbide crystal.

In an aspect, the present disclosure provides an example crystal growth system. In some implementations, the example crystal growth system includes a crucible at least partially defining a crystal growth chamber, the crystal growth chamber including a plurality of zones, each zone associated with a different processing profile. In some implementations, the example crystal growth system includes a silicon carbide crystal. In some implementations, the example crystal growth system includes a source material. In some implementations, the example crystal growth system includes an interface structure configured to separate at least two zones of the plurality of zones in the crystal growth system. In some implementations, the example crystal growth system includes a first heater about the crucible. In some implementations, the example crystal growth system includes a second heater about the crucible. In some implementations, the first heater is a different type of heater relative to the second heater.

In some implementations of the example crystal growth system, the first heater is an inductive heat source and the second heater is a resistive heat source.

In some implementations of the example crystal growth system, the first heater is a resistive heat source and the second heater is an inductive heat source.

In some implementations of the example crystal growth system, at least one of the first heater or the second heater has a non-uniform density of heat distribution elements.

In some implementations of the example crystal growth system, the one or more heat distribution elements include variations in material properties in the heat distribution elements or intentional design features to impede or enhance the transfer of thermal energy.

In some implementations of the example crystal growth system, the non-uniform density has a highest density of heat distribution elements at a point about the interface structure.

In some implementations of the example crystal growth system, the crystal growth system further includes one or more control devices, the one or more control devices operable to independently control the first heater and the second heater.

In some implementations of the example crystal growth system, the crystal growth system further includes at least one sensor, wherein the sensor may be positioned such that data is obtained in at least one of a first zone or a second zone.

In some implementations of the example crystal growth system, the crystal growth system further includes a sensor window positioned on the crucible.

In some implementations of the example crystal growth system, the sensor window includes quartz.

In some implementations of the example crystal growth system, the sensor is one or more of a pyrometer or a thermocouple.

In some implementations of the example crystal growth system, the controller is operable to independently control at least one of the first heater or the second heater based on data obtained from the sensor.

In some implementations of the example crystal growth system, at least one of the first heater or the second heater is operable at a fixed proportion of power delivery.

In some implementations of the example crystal growth system, the interface structure includes a baffle.

In some implementations of the example crystal growth system, the plurality of zones includes a first zone associated with a first processing profile and a second zone associated with a second processing profile.

In some implementations of the example crystal growth system, the first processing profile includes a first temperature profile, a first pressure, and a first vapor transport flux and the second processing profile includes a second temperature profile, a second pressure, and a second vapor transport flux.

In some implementations of the example crystal growth system, the first temperature profile is different from the second temperature profile.

In some implementations of the example crystal growth system, the first pressure is different from the second pressure.

In some implementations of the example crystal growth system, the first vapor transport flux is different from the second vapor transport flux.

In some implementations of the example crystal growth system, at least one of first heater or the second heater includes a tapered coil.

In some implementations of the example crystal growth system, the interface structure is at a location that is closer to the silicon carbide crystal relative to the source material.

In some implementations of the example crystal growth system, the interface structure is positioned in a range of about 0.5 centimeter to about 10 centimeters from a seed holder.

In some implementations of the example crystal growth system, a first zone of the plurality of zones of the crystal growth chamber is associated with a first diameter and a second zone of the plurality of zones of the crystal growth chamber is associated with a second diameter, the first diameter being larger than the second diameter.

In some implementations of the example crystal growth system, the interface structure reduces a thermal interaction between two of the plurality of zones.

In some implementations of the example crystal growth system, the interface structure includes a graphite material.

In some implementations of the example crystal growth system, the interface structure includes a porous graphite material.

In some implementations of the example crystal growth system, the interface structure includes one or more apertures.

In some implementations of the example crystal growth system, the interface structure includes a coating.

In some implementations of the example crystal growth system, the coating is a patterned coating on a surface facing the silicon carbide crystal.

In some implementations of the example crystal growth system, the system further includes a ring crystallizer structure at least partially surrounding the silicon carbide crystal.

In some implementations of the example crystal growth system, the ring crystallizer structure includes a carbide material.

In some implementations of the example crystal growth system, the ring crystallizer structure includes tantalum carbide.

In some implementations of the example crystal growth system, the system further includes an insulator structure within the crucible at least partially surrounding the silicon carbide crystal.

In some implementations of the example crystal growth system, the insulator structure includes graphite.

In an aspect, the present disclosure provides an example crystalline material. In some implementations, the example crystalline material includes a crucible at least partially defining a crystal growth chamber, the crystal growth chamber comprising a first zone and a second zone. In some implementations, the example crystalline material includes a silicon carbide crystal. In some implementations, the example crystalline material includes a source material. In some implementations, the example crystalline material includes one or more pumping circuits configured to provide a different processing profile in the first zone relative to the second zone.

In some implementations of the example crystal growth system, the one or more pumping circuits include a first pumping circuit associated with the first zone and a second pumping circuit associated with the second zone.

In some implementations of the example crystal growth system, the one or more pumping circuits provide one or more of a different flux, local pressure, or composition in the first zone relative to the second zone.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A crystal growth system for growing crystalline material, the crystalline material comprising silicon carbide, the crystal growth system comprising:
a crucible at least partially defining a crystal growth chamber, the crystal growth chamber comprising a plurality of zones, each zone associated with a different processing profile,
a silicon carbide crystal; and
a source material;
an interface structure configured to separate at least two zones of the plurality of zones in the crystal growth system.

2. The crystal growth system of claim 1, wherein the interface structure comprises a baffle.

3. The crystal growth system of claim 1, wherein the plurality of zones comprises a first zone associated with a first processing profile and a second zone associated with a second processing profile.

4. The crystal growth system of claim 3, wherein the first processing profile comprises a first temperature profile, a first pressure, and a first vapor transport flux and the second processing profile comprises a second temperature profile, a second pressure, and a second vapor transport flux.

5. The crystal growth system of claim 1, wherein the crystal growth system comprises a first heater for a first zone of the plurality of zones and a second heater for a second zone of the plurality of zones.

6. The crystal growth system of claim 5, wherein at least a portion of the first heater overlaps with at least a portion of the second heater.

7. The crystal growth system of claim 5, wherein the crystal growth system further comprises a third heater between the first heater and the second heater, the third heater being disposed at a vertical location at least partially about the interface structure.

8. The crystal growth system of claim 5, wherein at least one of first heater or the second heater comprises a tapered coil.

9. The crystal growth system of claim 5, wherein at least one of the first heater or the second heater has a non-uniform density of heat distribution elements.

10. The crystal growth system of claim 5, wherein at least one of the first heater or the second heater comprises a resistive heater or a radiofrequency heater.

11. The crystal growth system of claim 5, wherein at least one of the first heater or the second heater is movable during a crystal growth process.

12. The crystal growth system of claim 1, wherein the interface structure is at a location that is closer to the silicon carbide crystal relative to the source material.

13. The crystal growth system of claim 1, wherein a first zone of the plurality of zones of the crystal growth chamber is associated with a first diameter and a second zone of the plurality of zones of the crystal growth chamber is associated with a second diameter, the first diameter being larger than the second diameter.

14. The crystal growth system of claim 1, wherein the interface structure comprises a graphite material.

15. The crystal growth system of claim 1, wherein the interface structure comprises a coating, wherein the coating is a patterned coating on a surface facing the silicon carbide crystal.

16. The crystal growth system of claim 1, wherein the system further comprises a ring crystallizer structure at least partially surrounding the silicon carbide crystal.

17. The crystal growth system of claim 1, wherein the system further comprises an insulator structure within the crucible at least partially surrounding the silicon carbide crystal.

18. The crystal growth system of claim 1, wherein the interface structure is positioned in a range of about 0.5 centimeter to about 10 centimeters from a seed holder.

19. A crystal growth system for growing crystalline material, the crystalline material comprising silicon carbide, the crystal growth system comprising:
a crucible at least partially defining a crystal growth chamber, the crystal growth chamber comprising a first zone and a second zone;
a source material in the first zone;
a silicon carbide crystal in the second zone;
an interface structure configured to separate the first zone and the second zone, the interface structure positioned at a location closer to the silicon carbide crystal relative to the source material.

20. A crystal growth system for growing crystalline material, the crystalline material comprising silicon carbide, the crystal growth system comprising:
a crucible at least partially defining a crystal growth chamber;
a silicon carbide crystal; and
a source material;
a first heater about the crucible;
a second heater about the crucible;
wherein the first heater and the second heater are configured to alter a temperature profile of at least a portion of the crucible through cumulative heat production.
